(19) United States
(12) Patent Application Publication
(10) Pub. No.: US 2013/0134390 A1
(43) Pub. Date: May 30, 2013

(54) LIGHT-EMITTING DIODE, LIGHT-EMITTING DIODE LAMP, AND ILLUMINATION DEVICE

(71) Applicant: Noriyuki Aihara, Chichibu-shi (JP)

(72) Inventor: Noriyuki Aihara, Chichibu-shi (JP)

(73) Assignee: SHOWA DENKO K.K., Minato-ku, Tokyo (JP)

(21) Appl. No.: 13/814,858

(22) PCT Filed: Aug. 10, 2011
(86) PCT No.: PCT/JP2011/068256

§ 371 Date: Feb. 7, 2013

(30) Foreign Application Priority Data
Aug. 10, 2010 (JP) 2010-179475

(51) Int. Cl. H01L 33/04

(52) U.S. Cl. CPC H01L 33/04
USPC 257/13

(57) ABSTRACT

A light-emitting diode of the present invention includes a light-emitting unit, containing an active layer having a quantum well structure prepared by alternately stacking a well layer and a barrier layer each formed from a compound semiconductor having a composition formula of (Al_{X1}Ga_{1-X1})As (wherein 0≦X1≦1), and a first cladding layer and a second cladding layer that sandwich the active layer, a current diffusion layer formed on the light-emitting unit, and a functional substrate bonded to the current diffusion layer, wherein the first cladding layer and the second cladding layer are formed from a compound semiconductor having a composition formula of (Al_{X2}Ga_{1-X2})_{Y1}In_{1-Y1}P (wherein 0≦X2≦1 and 0≦Y1≦1), and the number of pairs of the well layer and the barrier layer is not more than five.

### TECHNICAL FIELD

The present invention relates to a light-emitting diode, a light-emitting diode lamp, and an illumination device, and relates particularly to a light-emitting diode, a light-emitting diode lamp, and an illumination device which emit red light or infrared light, and exhibit rapid response characteristics and high output characteristics.

### BACKGROUND ART

Light-emitting diodes that emit red light or infrared light are being used in an increasingly wide range of applications, including communication, various sensors, night illumination, and as light sources for plant factories.

Depending on the application, the requirements for these light-emitting diodes that emit red light or infrared light may vary, from applications that mainly emphasize high output characteristics or mainly emphasize rapid response characteristics, to applications that emphasize the importance of both these characteristics. In the case of light-emitting diodes used for communication applications, in order to achieve large-volume optical space transmission, both rapid response characteristics and high output characteristics are essential.

Examples of known light-emitting diodes for emitting red light or infrared light include light-emitting diodes produced by using a liquid phase epitaxial method to grow compound semiconductor layers including an AlGaAs active layer on a GaAs substrate. (for example, see Patent Documents 1 to 4).

Patent Document 4 discloses a so-called substrate-free light-emitting diode in which a liquid phase epitaxial method is used to grow compound semiconductor layers including an AlGaAs active layer on a GaAs substrate, and the GaAs substrate that was used as the growth substrate is subsequently removed. In the light-emitting diode disclosed in Patent Document 4, the output for a response time (rise time) of approximately 40 to 55 nsec is not more than 4 mW. Further, for a response time of approximately 20 nsec, the output slightly exceeds 5 mW, and it is thought that this currently represents the fastest response time for a high-output light-emitting diode produced using a liquid epitaxial method.

### PRIOR ART DOCUMENTS

### Patent Documents

### [Patent Document 1]

Japanese Unexamined Patent Application, First Publication No. Hei 6-21507

### [Patent Document 2]

Japanese Unexamined Patent Application, First Publication No. 2001-274454

### [Patent Document 3]

Japanese Unexamined Patent Application, First Publication No. Hei 7-38148

### [Patent Document 4]

Japanese Unexamined Patent Application, First Publication No. 2006-190792

### DISCLOSURE OF INVENTION

### Problems to be Solved by the Invention

However, the type of output mentioned above is insufficient for light-emitting diodes used for communication applications.

Unlike semiconductor lasers, light-emitting diodes utilize spontaneously emitted light, and therefore rapid response characteristics and high output characteristics exist in a trade-off type relationship. Accordingly, even if, for example, the thickness of the light-emitting layer is simply reduced to increase the carrier confinement effect, thereby enhancing the probability of emissive recombination between electrons and electron holes to achieve more rapid response characteristics, a problem arises in that the emission output decreases. The expression “carrier confinement effect” describes an effect in which a potential barrier created at the interface between the light-emitting layer (namely the active layer) and the cladding layer confines the carrier within the active layer region.

The present invention has been developed in light of the above circumstances, and has an object of providing a light-emitting diode, a light-emitting diode lamp, and an illumination device that emit red light and/or infrared light, and combine rapid response characteristics with high output characteristics.

### Means to Solve the Problems

As a result of intensive research aimed at achieving the above object, the inventors of the present invention discovered that by using, as the active layer, a quantum well structure prepared by alternately stacking not more than five pairs of an AlGaAs well layer and a barrier layer formed from AiGaAs or a quaternary mixed crystal of AlGaInP, using layers formed from a quaternary mixed crystal of AlGaInP as the cladding layers that sandwich the active layer, and epitaxially growing a compound semiconductor layer containing the active layer and the cladding layers on a growth substrate, subsequently removing the growth substrate, and then re-affixing (bonding) the compound semiconductor layer to a transparent substrate, a light-emitting diode could be completed which retains rapid response characteristics while emitting red light and/or infrared light at a high output.

In this structure, the inventors firstly employed a quantum well structure having a high carrier confinement effect that was suitable for achieving rapid response characteristics as the active layer, and then in order to ensure a high injected carrier density, they limited the number of pairs of the well layer and the barrier layer to 5 or fewer. By using this structure, the inventors were able to obtain a response time that was similar or even superior to the aforementioned fastest response time for a light-emitting diode produced using a liquid epitaxial method.

Further, for the cladding layers that sandwich either the ternary mixed crystal quantum well structure, or the quantum well structure composed of a ternary mixed crystal well layer and a quaternary mixed crystal barrier layer, the inventors employed a quaternary mixed crystal of AlGaInP, which has a large band gap, is transparent to the emission wavelength, and exhibits good crystallinity as a result of not containing As which is prone to developing defects.

Furthermore, among conventional light-emitting diodes that use an AlGaAs-based active layer, there are no examples of structures in which the compound semiconductor layer containing the active layer is affixed (bonded) to a transparent substrate, and the GaAs substrate used for growing the compound semiconductor layer has simply been used. However, GaAs substrates are not transparent to the light from the AlGaAs-based active layer, and because light absorption cannot be avoided, the inventors employed a structure in which this light absorption is prevented by removing the GaAs substrate used as the growth substrate following completion of the growing of the compound semiconductor layer, and then affixing (bonding) the compound semiconductor layer to a transparent substrate which can be expected to contribute to a higher output.

As described above, the inventors of the present invention ensured rapid response characteristics by employing a structure in which a quantum well structure containing not more than five pairs is used as the active layer, and then for this structure, they succeeded in increasing the output by employing an innovative combination in which a quaternary mixed crystal is used as the cladding layers that sandwich the ternary mixed crystal quantum well structure, and employing a structure in which the growth substrate used for growing the compound semiconductor layer is removed, and the compound semiconductor layer is then re-bonded to a substrate that does not absorb light.

The present invention provides the aspects described below.

(1) A light-emitting diode, including:

a light-emitting unit, containing an active layer having a quantum well structure prepared by alternately stacking a well layer and a barrier layer each formed from a compound semiconductor having a composition formula of (Al_{X1}Ga_{1-X1})As (wherein 0≦X1≦1), and a first cladding layer and a second cladding layer that sandwich the active layer,

a current diffusion layer formed on the light-emitting unit, and

a functional substrate bonded to the current diffusion layer, wherein

the first cladding layer and the second cladding layer are formed from a compound semiconductor having a composition formula of (Al_{X2}Ga_{1-X2})_{Y1}In_{1-Y1}P (wherein 0≦X2≦1 and 0≦Y1≦1), and

the number of pairs of the well layer and the barrier layer is not more than five.

(2) A light-emitting diode, including:

a light-emitting unit, containing an active layer having a quantum well structure prepared by alternately stacking a well layer formed from a compound semiconductor having a composition formula of (Al_{X1}Ga_{1-X1})As (wherein 0≦X1≦1) and a barrier layer formed from a compound semiconductor having a composition formula of (Al_{X3}Ga_{1-X3})_{Y2}In_{1-Y2}P (wherein 0≦X3≦1 and 0≦Y2≦1), and a first cladding layer and a second cladding layer that sandwich the active layer,

a current diffusion layer formed on the light-emitting unit, and

a functional substrate bonded to the current diffusion layer, wherein

the first cladding layer and the second cladding layer are formed from a compound semiconductor having a composition formula of (Al_{X2}Ga_{1-X2})_{Y1}In_{1-Y1}P (wherein 0≦X2≦1 and 0≦Y1≦1), and the number of pairs of the well layer and the barrier layer is not more than five.

(3) The light-emitting diode according to aspect (1) or (2), wherein the junction area between the active layer and each cladding layer is within a range from 20,000 to 90,000 μm².

In those cases where the active layer and the cladding layer are joined together via another layer such as a guide layer, the “junction area between the active layer and each cladding layer” also implies the junction area between this other layer and the active layer or cladding layer.

(4) The light-emitting diode according to any one of aspects (1) to (3), wherein the Al composition X1 of the well layer satisfies 0.20≦X1≦0.36, the thickness of the well layer is within a range from 3 to 30 nm, and the emission wavelength is set to 660 to 720 nm.
(5) The light-emitting diode according to any one of aspects (1) to (3), wherein the Al composition X1 of the well layer satisfies 0≦X1≦0.2, the thickness of the well layer is within a range from 3 to 30 nm, and the emission wavelength is set to 720 to 850 nm.
(6) The light-emitting diode according to any one of aspects (1) to (5), wherein the functional substrate is transparent to an emission wavelength.
(7) The light-emitting diode according to any one of aspects (1) to (6), wherein the functional substrate is formed from GaP, sapphire or SiC.
(8) A light-emitting diode, including:

a light-emitting unit, containing an active layer having a quantum well structure prepared by alternately stacking a well layer and a barrier layer each formed from a compound semiconductor having a composition formula of (Al_{X1}Ga_{1-X1})As (wherein 0≦X1≦1), and a first cladding layer and a second cladding layer that sandwich the active layer,

a current diffusion layer formed on the light-emitting unit, and

a functional substrate, which contains a reflective layer that is disposed facing the light-emitting unit and has a reflectance of at least 90% relative to the emission wavelength, and which is bonded to the current diffusion layer, wherein the first cladding layer and the second cladding layer are formed from a compound semiconductor having a composition formula of (Al_{X2}Ga_{1-X2})_{Y1}In_{1-Y1}P (wherein 0≦X2≦1 and 0≦Y1≦1), and

the number of pairs of the well layer and the barrier layer is not more than five.

(9) A light-emitting diode, including:

a light-emitting unit, containing an active layer having a quantum well structure prepared by alternately stacking a well layer formed from a compound semiconductor having a composition formula of (Al_{X1}Ga_{1-X1})As (wherein 0≦X1≦1) and a barrier layer formed from a compound semiconductor having a composition formula of (Al_{X3}Ga_{1-X3})_{Y2}In_{1-Y2}P (wherein 0≦X3≦1 and 0≦Y2≦1), and a first cladding layer and a second cladding layer that sandwich the active layer,

a current diffusion layer formed on the light-emitting unit, and

a functional substrate, which contains a reflective layer that is disposed facing the light-emitting unit and has a reflectance of at least 90% relative to the emission wavelength, and which is bonded to the current diffusion layer, wherein

the first cladding layer and the second cladding layer are formed from a compound semiconductor having a composition formula of (Al_{X2}Ga_{1-X2})_{Y1}In_{1-Y1}P (wherein 0≦X2≦1 and 0≦Y1≦1), and

the number of pairs of the well layer and the barrier layer is not more than five.

(10) The light-emitting diode according to aspect (8) or (9), wherein the junction area between the active layer and each cladding layer is within a range from 20,000 to 90,000
(11) The light-emitting diode according to any one of aspects (8) to (10), wherein the Al composition X1 of the well layer satisfies 0.20≦X1≦0.36, the thickness of the well layer is within a range from 3 to 30 nm, and the emission wavelength is set to 660 to 720 nm.
(12) The light-emitting diode according to any one of aspects (8) to (10), wherein the Al composition X1 of the well layer satisfies 0≦X1≦0.2, the thickness of the well layer is within a range from 3 to 30 nm, and an emission wavelength is set to 720 to 850 nm.
(13) The light-emitting diode according to any one of aspects (8) to (12), wherein the functional substrate contains a layer formed from silicon or germanium.
(14) The light-emitting diode according to any one of aspects (8) to (12), wherein the functional substrate contains a metal substrate.
(15) The light-emitting diode according to aspect (14), wherein the metal substrate is formed from two or more metal layers.
(16) The light-emitting diode according to any one of aspects (1) to (15), wherein the current diffusion layer is formed from GaP.
(17) The light-emitting diode according to any one of aspects (1) to (16), wherein the thickness of the current diffusion layer is within a range from 0.5 to 20 μm.
(18) The light-emitting diode according to any one of aspects (1) to (17), wherein the side surface of the functional substrate has a vertical surface, which is positioned relatively closer to the light-emitting unit and is substantially perpendicular to a main light extraction surface, and an inclined surface, which is positioned relatively distant from the light-emitting unit and is inclined inward relative to the main light extraction surface.
(19) The light-emitting diode according to aspect (18), wherein the light extraction surface includes a rough surface.
(20) The light-emitting diode according to aspect (18) or (19), wherein a first electrode and a second electrode are provided on the light-emitting diode on the side of the main light extraction surface.
(21) The light-emitting diode according to aspect (20), wherein the first electrode and the second electrode are ohmic electrodes.
(22) The light-emitting diode according to aspect (20) or (21), further including a third electrode, which is provided on the surface of the functional substrate on the opposite side to the surface facing the main light extraction surface.
(23) A light-emitting diode lamp including the light-emitting diode according to any one of aspects (1) to (22).
(24) A light-emitting diode lamp including the light-emitting diode according to aspect (22), wherein the first electrode or the second electrode, and the third electrode are connected substantially equipotentially.
(25) An illumination device, equipped with two or more of the light-emitting diode according to any one of aspects (1) to (22).

In the present invention, the term “functional substrate” describes a substrate which, following growth of the compound semiconductor layer on a growth substrate and subsequent removal of the growth substrate, is bonded to the compound semiconductor layer via the current diffusion layer so as to support the compound semiconductor layer. In those cases where a prescribed layer is formed on the current diffusion layer, and a prescribed substrate is then bonded to the prescribed layer, the structure including the prescribed layer is referred to as the “functional substrate”.

### Effects of the Invention

The light-emitting diode of the present invention employs an active layer having a quantum well structure prepared by alternately stacking a well layer and a barrier layer formed from AlGaAs, or an active layer having a quantum well structure prepared by alternately stacking a well layer formed from AlGaAs and a barrier layer formed from AlGaInP, and has a structure that uses a quantum well having a large injected carrier confinement effect. As a result, by ensuring satisfactory confinement of the injected carrier within the well layer, the carrier density in the well layer increases, resulting in an increased probability of emissive recombination and an improved response time.

Further, because of wave nature of the carrier injected into the quantum well structure, the carrier diffuses to the entire area of the well layers within the quantum well structure by a tunneling effect. However, because a structure is employed in which the number of pairs of the well layer and the barrier layer within the quantum well structure is limited to five or fewer, any deterioration in the injected carrier confinement effect caused by this diffusion is effectively avoided, and the rapid response characteristics are retained. The number of pairs of the well layer and the barrier layer in the quantum well structure is preferably not more than three, and is more preferably one.

Furthermore, because the structure emits light from an active layer having a quantum well structure, the monochromaticity is excellent.

Further, the first cladding layer and the second cladding layer that sandwich the active layer employ structures formed from AlGaJnP, which is transparent to the emission wavelength and exhibits good crystallinity as a result of not containing As, which is prone to defects. As a result, the probability of non-emissive recombination between an electron and an electron hole via a defect is reduced, and the emission output is improved.

Moreover, structures formed from a quaternary mixed crystal of AlGaInP are employed as the first cladding layer and the second cladding layer that sandwich the active layer, and therefore the Al concentration is lower than a light-emitting diode in which the cladding layers are formed from a ternary mixed crystal, yielding an improvement in the moisture resistance.

In addition, a structure is employed in which the growth substrate used for the compound semiconductor layer is removed and a functional substrate is bonded to the current diffusion layer, and therefore light absorption by the growth substrate is avoided, and the emission output is improved. In other words, because the GaAs substrate that is typically used as the growth substrate for the compound semiconductor layer has a band gap that is narrower than the band gap of the active layer, light from the active layer is absorbed by the GaAs substrate, causing a deterioration in the light extraction efficiency, but by removing this GaAs substrate, the emission output can be improved.

In the light-emitting diode of the present invention, the junction area between the active layer and each cladding layer is preferably within a range from 20,000 to 90,000 μm². By ensuring that this junction area is not more than 90,000 μm², the current density can be increased, and a high output can be retained, while the probability of emissive recombination increases, yielding an improvement in the response time. On the other hand, by ensuring that the junction area is at least 20,000 μm², saturation of the emission output relative to the current flow can be suppressed, enabling any large reduction in the emission output to be avoided, and enabling a high output to be maintained. The junction area between the active layer and each cladding layer is preferably within a range from 20,000 to 53,000 μm².

In one aspect of the light-emitting diode of the present invention, it is preferable that the Al composition X1 of the well layer satisfies 0.20≦X1≦0.36, the thickness of the well layer is within a range from 3 to 30 nm, and the emission wavelength is set within a range from 660 to 720 nm. This enables a faster response time and a higher output to be achieved than conventional red light-emitting diodes of 660 to 720 nm.

Further, in another aspect of the light-emitting diode of the present invention, it is preferable that the Al composition X1 of the well layer satisfies 0≦X1≦0.2, the thickness of the well layer is within a range from 3 to 30 nm, and the emission wavelength is set within a range from 720 to 850 nm. This enables a faster response time and a higher output to be achieved than conventional red light-emitting diodes of 720 to 850 nm.

In the light-emitting diode of the present invention, be employing a structure in which the functional substrate is transparent relative to the emission wavelength, a higher output can be achieved than light-emitting diodes that use a substrate which absorbs light.

In the light-emitting diode of the present invention, by employing a structure in which the functional substrate is formed from GaP, sapphire or SiC, because the material is resistant to corrosion, the moisture resistance is improved.

In the light-emitting diode of the present invention, by employing a structure in which both the functional substrate and the current diffusion layer are formed from GaP, the bonding strength between the two can be improved.

### BRIEF DESCRIPTION OF THE DRAWINGS

FIG. 1 is a plan view of a light-emitting diode lamp that uses a light-emitting diode according to an embodiment of the present invention.

FIG. 2 is a schematic cross-sectional view, along the line A-A′ in FIG. 1, of a light-emitting diode lamp that uses a light-emitting diode according to an embodiment of the present invention.

FIG. 3 is a plan view of a light-emitting diode according to an embodiment of the present invention.

FIG. 4 is a schematic cross-sectional view, along the line B-B′ in FIG. 3, of a light-emitting diode according to an embodiment of the present invention.

FIG. 5 is an diagram describing the structure of an active layer in a light-emitting diode according to an embodiment of the present invention.

FIG. 6 is a schematic cross-sectional view of an epiwafer used in a light-emitting diode according to an embodiment of the present invention.

FIG. 7 is a schematic cross-sectional view of a bonded wafer used in a light-emitting diode according to an embodiment of the present invention.

FIG. 8A is a plan view of a light-emitting diode according to another embodiment of the present invention.

FIG. 8B is a schematic cross-sectional view, along the line C-C′ in FIG. 8A.

FIG. 9 is a graph illustrating the relationship between the number of pairs and the output and response time for a light-emitting diode according to an embodiment of the present invention (for the case in which the junction area between the active layer and each cladding layer is 123,000 μm²).

FIG. 10 is a graph illustrating the relationship between the number of pairs and the output and response time for a light-emitting diode according to an embodiment of the present invention (for the case in which the junction area between the active layer and each cladding layer is 53,000 μm²).

FIG. 11 is a schematic cross-sectional view of a light-emitting diode according to yet another embodiment of the present invention.

### EMBODIMENTS OF THE INVENTION

A detailed description of a light-emitting diode, which represents one embodiment of the application of the present invention, and a light-emitting diode lamp that uses the light-emitting diode, is presented below with reference to the drawings. In the drawings used in the following description, members that are the same are either labeled with the same symbol, or are left unlabeled. Further, the drawings used in the following description are schematic, and the dimensional ratios between lengths, widths and thicknesses may differ from the actual ratios.

### <Light-Emitting Diode Lamp>

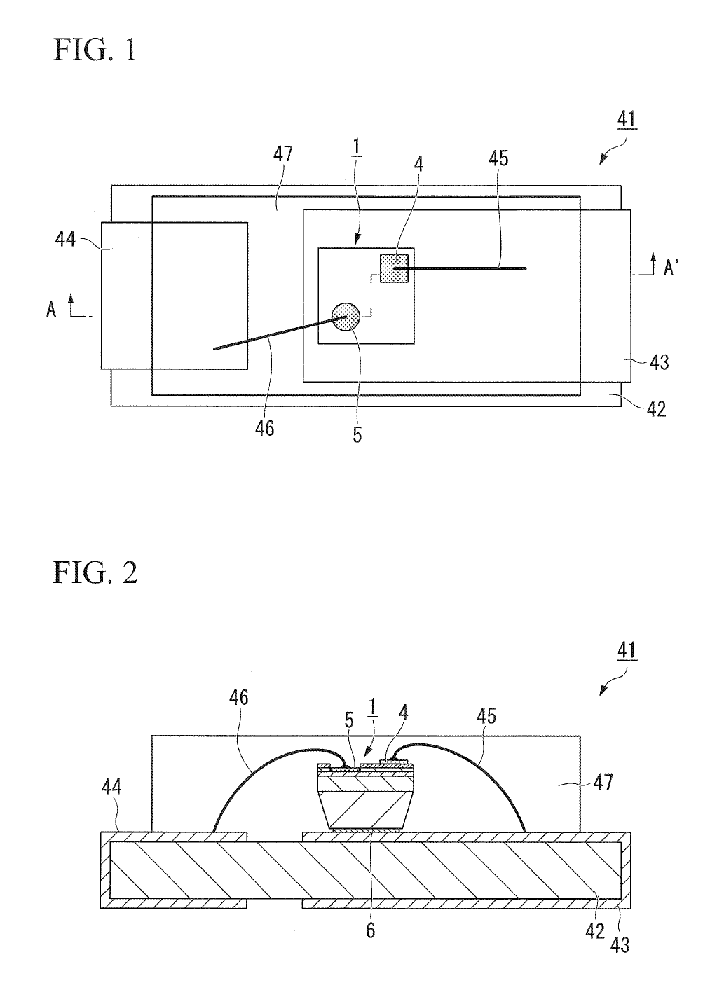

FIG. 1 and FIG. 2 are diagrams for describing a light-emitting diode lamp that uses a light-emitting diode that represents one embodiment of the application of the present invention, wherein FIG. 1 is a plan view and FIG. 2 is a cross-sectional view along the line A-A′ in FIG. 1.

As illustrated in FIG. 1 and FIG. 2, a light-emitting diode lamp 41 that uses a light-emitting diode 1 of the present embodiment has a structure in which at least one light-emitting diode 1 is mounted on the surface of a mounting substrate 42.

More specifically, an n-electrode terminal 43 and a p-electrode terminal 44 are provided on the surface of the mounting substrate 42. Further, an n-type ohmic electrode 4 that acts as a first electrode for the light-emitting diode 1 and the n-electrode terminal 43 on the mounting substrate 42 are connected using a gold wire 45 (wire bonding). On the other hand, a p-ohmic electrode 5 that acts as a second electrode for the light-emitting diode 1 and the p-electrode terminal 44 on the mounting substrate 42 are connected using a gold wire 46. Moreover, as illustrated in FIG. 2, a third electrode 6 is provided on the opposite surface of the light-emitting diode 1 to the surface on which the n-type and p-type ohmic electrodes 4 and 5 are provided, and the light-emitting diode 1 is connected to the n-electrode terminal 43 and secured to the mounting substrate 42 via this third electrode 6. The n-ohmic electrode 4 and the third electrode 6 are connected electrically via the n-electrode terminal 43 so as to be equipotential or substantially equipotential. By providing the third electrode, if an excessive reverse voltage is applied, then overcurrent can be prevented from flowing into the active layer, and rather flows between the third electrode and the p-type electrode, meaning damage of the active layer can be prevented. A reflective structure may also be added at the interface between the third electrode and the substrate to increase the output. Furthermore, by adding a eutectic metal or solder or the like to the surface of the third electrode, simplified assembly techniques such as eutectic die bonding or the like can be used. The surface of the mounting substrate 42 on which the light-emitting diode 1 is mounted is sealed using a typical sealing resin 47 such as a silicon resin or epoxy resin.

### Light-Emitting Diode

### First Embodiment

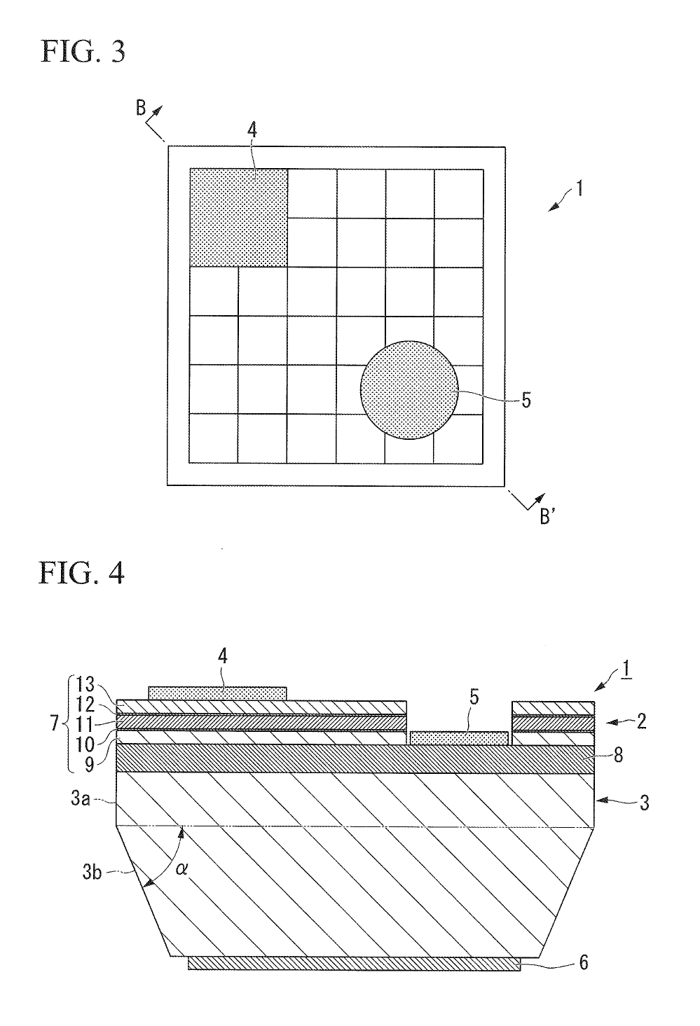

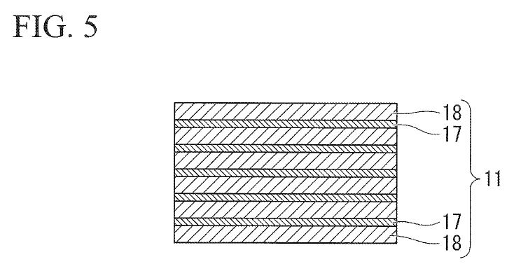

FIG. 3 and FIG. 4 are diagrams describing a light-emitting diode according to a first embodiment of the present invention, wherein FIG. 3 is a plan view and FIG. 4 is a cross-sectional view along the line B-B′ in FIG. 3. Further, FIG. 5 is a cross-sectional view of the stacked structure.

The light-emitting diode according to this first embodiment includes a light-emitting unit 7, containing an active layer 11 having a quantum well structure formed by alternately stacking a well layer 17 and a barrier layer 18 each formed from a compound semiconductor having a composition formula of (Al_{X1}Ga_{1-X1})As (wherein 0≦X1≦1), and a first cladding layer 9 and a second cladding layer 13 that sandwich the active layer 11, a current diffusion layer 8 formed on the light-emitting unit 7, and a functional substrate 3 that is bonded to the current diffusion layer 8, wherein the first and second cladding layers 9 and 13 are formed from a compound semiconductor having a composition formula of (Al_{X2}Ga_{1-X2})_{Y1}In_{1-Y1}P (wherein 0≦X2≦1 and 0≦Y1≦1), and the number of pairs of the well layer 17 and the barrier layer 18 is not more than five.

In this embodiment, the main light extraction surface refers to the surface of the compound semiconductor layer 2 on the opposite side to the surface that is bonded to the functional substrate 3.

As illustrated in FIG. 4, the compound semiconductor layer 2 (also referred to as the epitaxial growth layer) has a structure in which the pn junction-type light-emitting unit 7 and the current diffusion layer 8 are stacked sequentially. The structure of this compound semiconductor layer 2 may also include conventional functional layers when required. For example, conventional layers such as a contact layer for reducing the contact resistance of the ohmic electrodes, a current diffusion layer for achieving planar diffusion of the device drive current across the entire light-emitting unit, or in contrast, a current inhibition layer or current constriction layer for restricting the region through which the device drive current is able to flow, may be provided. The compound semiconductor layer 2 is preferably formed by epitaxial growth on top of a GaAs substrate.

As illustrated in FIG. 4, the light-emitting unit 7 is formed by sequentially stacking at least a p-type lower cladding layer (the first cladding layer) 9, a lower guide layer 10, the active layer 11, an upper guide layer 12 and an n-type upper cladding layer (the second cladding layer) 13 on the current diffusion layer 8. In other words, in terms of obtaining high-intensity light emission, the light-emitting unit 7 is preferably a so-called double hetero (abbreviation: DH) structure including the lower cladding layer 9 and the lower guide layer 10, and the upper guide layer 12 and the upper cladding layer 13, which are positioned in opposing positions on the lower and upper sides of the active layer 11 to “confine” emitted light and carriers that give rise to radiative recombination within the active layer 11.

As illustrated in FIG. 5, the active layer 11 has a quantum well structure for controlling the emission wavelength of the light-emitting diode (LED). In other words, the active layer 11 is a multilayer structure (stacked structure) composed of the well layers 17 and the barrier layers 18, in which a barrier layer 18 is positioned at each of the two outer edges of the structure. For example, in the case of a quantum well structure containing five pairs, the active layer 11 is composed of five layers of the well layer 17 and six layers of the barrier layer 18.

The thickness of the active layer 11 is preferably within a range from 0.02 to 2 μm. Further, there are no particular limitations on the type of conductivity of the active layer 11, and any of undoped, p-type or n-type conductivity may be selected. In order to enhance the light emission efficiency, it is preferable to use an undoped active layer or a layer in which the carrier concentration is restricted to less than 3×10¹⁷ cm⁻³ in order to achieve good crystallinity. By improving the crystallinity and reducing defects, light absorption can be suppressed, and the emission output can be improved.

The well layer 17 is formed from a compound semiconductor having a composition formula of (Al_{X1}Ga_{1-X1})As (wherein 0≦X1≦1).

The Al composition X1 preferably satisfies 0≦X1≦0.36. By ensuring that the Al composition X1 satisfies this range, a layer having a desired emission wavelength within a range from 660 to 850 nm can be obtained.

Table 1 illustrates the relationship between the Al composition X1 and the emission wavelength when the thickness of the well layer 17 is 7 nm.

It is evident that as the value of the Al composition X1 is lowered, the emission wavelength lengthens. Further, based on the trend observed in Table 1, the Al composition that corresponds with emission wavelengths not shown in the table can be estimated.

TABLE 1

| Peak wavelength (nm) | Al composition (X) |
|---|---|
| 660 | 0.31 |
| 680 | 0.27 |
| 700 | 0.23 |
| 720 | 0.19 |
| 730 | 0.17 |
| 760 | 0.12 |
| 800 | 0.05 |
| 830 | 0.02 |
| 850 | 0 |

The thickness of the well layer 17 is preferably within a range from 3 to 30 nm. The thickness is more preferably from 3 to 10 nm.

Table 2 illustrates the relationship between the thickness of the well layer 17 and the emission wavelength when the Al composition X1 of the well layer 17=0.23. Table 3 illustrates the relationship between the thickness of the well layer 17 and the emission wavelength when the Al composition X1 of the well layer 17=0.17. Table 4 illustrates the relationship between the thickness of the well layer 17 and the emission wavelength when the Al composition X1 of the well layer 17=0.02. As the thickness of the layer is reduced, a quantum effect causes a shortening of the wavelength. At larger thickness values, the emission wavelength is determined by the layer composition. Further, based on the trends observed in the tables, the layer thickness that corresponds with emission wavelengths not shown in the tables can be estimated.

TABLE 2

| Peak wavelength (nm) | Layer thickness (nm) |
|---|---|
| 690 | 5 |
| 700 | 7 |
| 710 | 15 |
| 720 | 25 |

TABLE 3

| Peak wavelength (nm) | Layer thickness (nm) |
|---|---|
| 720 | 5 |
| 730 | 7 |
| 740 | 15 |
| 760 | 28 |

TABLE 4

| Peak wavelength (nm) | Layer thickness (nm) |
|---|---|
| 810 | 3 |
| 820 | 5 |
| 830 | 7 |
| 840 | 20 |

Based on the above relationships between the emission wavelength, and the Al composition X1 and the thickness of the well layer 17, the Al composition X1 and the thickness of the well layer 17 can be determined so as to obtain a desired emission wavelength within the range from 660 to 850 nm.

For example, by setting the Al composition X1 of the well layer 17 to satisfy 0.20≦X1≦0.36, and setting the thickness of the well layer 17 to a value within a range from 3 to 30 nm, a light-emitting diode having an emission wavelength of 660 to 760 nm can be produced.

Furthermore, by setting the Al composition X1 of the well layer 17 to satisfy 0≦X1≦0.2, and setting the thickness of the well layer 17 to a value within a range from 3 to 30 nm, a light-emitting diode having an emission wavelength of 760 to 850 nm can be produced.

The barrier layer 18 is formed from a compound semiconductor having a composition formula of (Al_{X}Ga_{1-X})As (wherein 0≦X≦1). In order to prevent absorption by the barrier layer 18 and enhance the light emission efficiency, X is preferably set so as to achieve a composition that has a band gap which is larger than the band gap of the well layer 17. Further, from the viewpoint of the crystallinity, the Al concentration is preferably low. Accordingly, X is preferably within a range from 0.1 to 0.4. The ideal value for X is determined in accordance with the relationship with the composition of the well layer. By improving the crystallinity and reducing defects, light absorption can be suppressed, and as a result, the emission output can be improved.

The thickness of the barrier layer 18 is preferably equal to the thickness of the well layer 17, or thicker than the thickness of the well layer 17. By ensuring an adequate thickness within the range in which tunneling effects occur, diffusion between well layers caused by tunneling can be suppressed, and the carrier confinement effect can be enhanced, thereby increasing the probability of emissive recombination of electrons and electron holes, resulting in an improved emission output.

In the light-emitting diode of the present invention, the number of pairs of the well layer 17 and the barrier layer 18 that are stacked alternately in the quantum well structure that constitutes the active layer 11 is not more than five, and may be one. By employing this structure, the carrier confinement effect is enhanced, the probability of emissive recombination between electrons and electron holes is increased, and a rapid response time (rise time) of 25 nsec or less can be achieved.

As shown in the examples described below, as the number of pairs of the well layer 17 and the barrier layer 18 is reduced from five pairs to one pair, the response time shortens. Under the conditions described in the examples, a fastest response time of 17 nsec was achieved when the number of pairs was one.

The fewer the number of quantum well layers, the narrower the region in which the electrons and electron holes are confined, and therefore the probability of emissive recombination increases, resulting in a more rapid response time.

As the numbers of the well layer 17 and the barrier layer 18 are reduced, the junction capacitance of the pn junction increases. This is because the well layer 17 and the barrier layer 18 are either undoped or have a low carrier concentration, and therefore they function as depletion layers in the pn junction, with a thinner depletion layer yielding a larger capacitance.

It is generally considered that a smaller capacitance is desirable for shortening the response time, but in the structure of the present invention, it was discovered that the response time could be shortened by reducing the number of layers of the well layer 17 and the barrier layer 18, despite the accompanying increase in the capacitance.

It is thought that this is because the increase in the rate of injected carrier recombination achieved by reducing the numbers of the well layer 17 and the barrier layer 18 is a more significant effect.

The junction area between the active layer 11 and the lower cladding layer 9 or the upper cladding layer 13 is preferably within a range from 20,000 to 90,000 μm².

By ensuring that the junction area between the active layer 11 and the lower cladding layer 9 or the upper cladding layer 13 is not more than 90,000 μm², the current density is increased and the probability of emissive recombination is increased, resulting in an improvement in the response time.

For example, as shown in the examples described below, when the junction area between the active layer 11 and the lower cladding layer 9 or the upper cladding layer 13 was set to either 123,000 μm² (350 μm×350 μm), or a narrower 53,000 μm² (230 μm×230 μm), the latter case yielded an improvement in the response time of approximately 10% when the number of pairs of the well layer 17 and the barrier layer 18 was five pairs, and yielded an improvement in the response time of 20% when the number of pairs was one pair.

On the other hand, by ensuring that the junction area between the active layer 11 and the lower cladding layer 9 or the upper cladding layer 13 is at least 20,000 μm², no significant reduction in the emission output occurs, and a high output can be maintained.

For example, as shown in the examples described below, when the junction area between the active layer 11 and the lower cladding layer 9 or the upper cladding layer 13 was set to 53,000 μm², the emission output was 9.6 mW (response time: 22 nsec) when the number of pairs of the well layer 17 and the barrier layer 18 was five pairs, but even when the number of pairs was only one pair, a high emission output of 9 mW (response time: 15 nsec) was able to be maintained.

As illustrated in FIG. 4, the lower guide layer 10 and the upper guide layer 12 are provided on the lower surface and the upper surface respectively of the active layer 11. Specifically, the lower guide layer 10 is provided on the lower surface of the active layer 11, and the upper guide layer 12 is provided on the upper surface of the active layer 11.

The lower guide layer 10 and the upper guide layer 12 have a composition represented by (Al_{X}Ga_{1-X})As (0≦X≦1). The value of the Al composition X is preferably a value that ensures that the band gap of the layer is equal to, or larger than, the band gap of the barrier layer 18, and a value within a range from 0.2 to 0.6 is particularly preferred. From the viewpoint of the crystallinity, the ideal value for X is determined in accordance with the relationship with the composition of the well layer. By improving the crystallinity and reducing defects, light absorption can be suppressed, and as a result, the emission output can be improved.

Table 5 shows the Al composition values X for the barrier layer 18 and the guide layer that yield maximum emission output of the emission wavelength when the thickness of the well layer 17 is 7 nm. It is preferable to use compositions that yield band gaps for the barrier layer and the guide layer that are larger than the band gap of the well layer, but the ideal compositions for enhancing the crystallinity and increasing the emission output are determined based on the relationship with the composition of the well layer. By improving the crystallinity and reducing defects, light absorption can be suppressed, and as a result, the emission output can be improved.

TABLE 5

| Peak | Well | Barrier | Guide |
|---|---|---|---|
| wavelength (nm) | (X) | (X) | (X) |
| 680 | 0.27 | 0.4 | 0.5 |
| 700 | 0.23 | 0.35 | 0.45 |
| 730 | 0.17 | 0.3 | 0.4 |
| 760 | 0.12 | 0.25 | 0.35 |
| 800 | 0.05 | 0.15 | 0.25 |
| 830 | 0.02 | 0.15 | 0.25 |
| 850 | 0 | 0.1 | 0.2 |

The lower guide layer 10 and the upper guide layer 12 are provided for the purpose of reducing the transmission of defects between the lower cladding layer 9 and the upper cladding layer 13 respectively, and the active layer 11. In other words, whereas the group V constituent element in the lower guide layer 10, the upper guide layer 12 and the active layer 11 is arsenic (As), in the present invention, the group V constituent element in the lower cladding layer 9 and the upper cladding layer 13 is phosphorus (P), and therefore defects are unlikely to occur at the respective interfaces. The transmission of defects to the active layer 11 is a cause of deterioration in the performance of the light-emitting diode. Accordingly, the thickness of the lower guide layer 10 and the upper guide layer 12 is preferably not less than 10 nm, and is more preferably within a range from 20 nm to 100 nm.

There are no particular limitations on the type of conductivity of the lower guide layer 10 and the upper guide layer 12, and any of undoped, p-type or n-type conductivity may be selected. In order to enhance the light emission efficiency, it is preferable to use an undoped layer or a layer in which the carrier concentration is restricted to less than 3×10¹⁷ cm⁻³ in order to achieve good crystallinity.

As illustrated in FIG. 4, the lower cladding layer 9 and the upper cladding layer 13 are provided on the lower surface of the lower guide layer 10 and the upper surface of the upper guide layer 12 respectively.

The lower cladding layer 9 and the upper cladding layer 13 are formed from a compound semiconductor represented by (Al_{X2}Ga_{1-X2})_{Y1}In_{Y1}P (wherein 0≦X2≦1 and 0≦Y1≦1), and are preferably formed from a material having a larger band gap than the barrier layer 18, and more preferably formed from a material having a larger band gap than the lower guide layer 10 and the upper guide layer 12. Examples of such materials include materials of the composition formula (Al_{X2}Ga_{1-X2})_{Y1}In_{1-Y1}P (wherein 0≦X2≦1 and 0≦Y1≦1) in which the Al composition X2 is within a range from 0.3 to 0.7. Further, Y1 is preferably within a range from 0.4 to 0.6.

The lower cladding layer 9 and the upper cladding layer 13 are formed with different polarities. Further, the carrier concentration and thickness of both the lower cladding layer 9 and the upper cladding layer 13 may be set within conventionally preferred ranges, and these conditions are preferably optimized so as to maximize the light emission efficiency of the active layer 11. Furthermore, warping of the compound semiconductor layer 2 can also be reduced by controlling the composition of the lower cladding layer 9 and the upper cladding layer 13.

Specifically, for the lower cladding layer 9, the use of a semiconductor material composed of a Mg-doped p-type (Al_{X2}Ga_{1-X2})_{Y1}In_{1-Y1}P (wherein 0.3≦X2≦0.7 and 0.4≦Y1≦0.6) is preferred. Further, the carrier concentration is preferably within a range from 2×10¹⁷ to 2×10¹⁸ cm⁻³, and the thickness is preferably within a range from 0.1 to 1 μm.

On the other hand, for the upper cladding layer 13, the use of a semiconductor material composed of a Si-doped n-type (wherein 0.3≦×2≦0.7 and 0.4≦Y1≦0.6) is preferred. Further, the carrier concentration is preferably within a range from 1×10¹⁷ to 1×10¹⁸ cm⁻³, and the thickness is preferably within a range from 0.1 to 1 μm. The polarities of the lower cladding layer 9 and the upper cladding layer 13 may be selected with due consideration of the device structure of the compound semiconductor layer 2.

Furthermore, conventional layer structures such as a contact layer for reducing the contact resistance of the ohmic electrodes, a current diffusion layer for achieving planar diffusion of the device drive current across the entire light-emitting unit, or in contrast, a current inhibition layer or current constriction layer for restricting the region through which the device drive current is able to flow, may be provided on top of the constituent layers of the light-emitting unit 7.

As illustrated in FIG. 4, the current diffusion layer 8 is provided beneath the light-emitting unit 7. This current diffusion layer 8 is provided for the purpose of alleviating the strain that is produced due to the active layer 11 during epitaxial growth of the compound semiconductor layer 2 on the GaAs substrate.

Further, the current diffusion layer 8 is preferably formed from a material that is transparent to the emission wavelength from the light-emitting unit 7 (the active layer 11), such as GaP. When GaP is used for the current diffusion layer 8, by using a GaP substrate for the functional substrate 3, bonding of the two can be simplified, and a superior bonding strength can be obtained.

Further, the thickness of the current diffusion layer 8 is preferably within a range from 0.5 to 20 μm. This is because if the thickness is less than 0.5 μm, then the current diffusion is unsatisfactory, whereas if the thickness is not less than 20 μm, then the costs associated with crystal growth of such a thickness increase undesirably. The thickness of the current diffusion layer 8 is more preferably within a range from 5 to 15 μm.

The functional substrate 3 is bonded to the surface of the compound semiconductor layer 2 on the opposite side to the main light extraction surface. In other words, as illustrated in FIG. 4, the functional substrate 3 is bonded to the current diffusion layer 8 that constitutes the compound semiconductor layer 2. The functional substrate 3 is formed from a material that has sufficient strength to mechanically support the light-emitting unit 7, is able to transmit the light emitted from the light-emitting unit 7, and is optically transparent to the emission wavelength from the active layer 11. Further, a material that is chemically stable and exhibits excellent moisture resistance is desirable. For example, a material that does not contain corrosion-prone Al or the like is preferred.

The functional substrate 3 is preferably formed from GaP, sapphire or SiC. Further, in order to enable the functional substrate 3 to mechanically support the light-emitting unit 7 with a satisfactory degree of strength, the thickness of the functional substrate 3 is preferably not less than approximately 50 μm. Furthermore, in order to facilitate mechanical processing of the functional substrate 3 following bonding to the compound semiconductor layer 2, the thickness of the functional substrate 3 preferably does not exceed approximately 300 μm. In other words, in terms of the degree of transparency and cost, the functional substrate 3 is most preferably formed from an n-type GaP substrate having a thickness of not less than approximately 50 μm and not more than approximately 300 μm.

Furthermore, as illustrated in FIG. 4, the side surface of the functional substrate 3 includes a vertical surface 3a that is positioned relatively closer to the compound semiconductor layer 2 and is substantially perpendicular to the main light extraction surface, and an inclined surface 3b that is positioned relatively distant from the compound semiconductor layer 2 and is inclined inward relative to the main light extraction surface. This structure enables light emitted toward the functional substrate 3 from the active layer 11 to be extracted externally with good efficiency. Of the light that is emitted from the active layer 11 toward the functional substrate 3, a portion of the light is reflected off the vertical surface 3a and can be extracted at the inclined surface 3b. On the other hand, light reflected off the inclined surface 3b can be extracted at the vertical surface 3a. In this mariner, a synergistic effect between the vertical surface 3a and the inclined surface 3b enables the light extraction efficiency to be enhanced.

Further, in this embodiment, as illustrated in FIG. 4, an angle α between the inclined surface 3b and a surface parallel to the light emission surface is preferably set within a range from 55 to 80 degrees. By employing an angle within this range, light reflected off the bottom of the functional substrate 3 can be extracted externally with good efficiency.

Furthermore, the depth (in the thickness direction) of the vertical surface 3a is preferably within a range from 30 to 100 μm. By ensuring that the depth of the vertical surface 3a satisfies this range, light reflected off the bottom of the functional substrate 3 can be returned efficiently through the vertical surface 3a to the light emission surface, and can then be emitted from the main light extraction surface. As a result, the light emission efficiency of the light-emitting diode 1 can be enhanced.

Furthermore, the inclined surface 3b of the functional substrate 3 is preferably subjected to a surface roughening treatment. Roughening the inclined surface 3b results in improved light extraction efficiency at the inclined surface 3b. In other words, by roughening the inclined surface 3b, total reflection at the inclined surface 3b is inhibited, enabling the light extraction efficiency to be improved. Here, “roughening” refers to the formation of very fine asperity on the surface using a chemical treatment or the like.

The bonding interface between the compound semiconductor layer 2 and the functional substrate 3 may sometimes act as a high-resistance layer. In other words, a high-resistance layer, which is not shown in the drawings, may sometimes be provided between the compound semiconductor layer 2 and the functional substrate 3. This high-resistance layer has a higher resistance than the functional substrate 3, and when provided, has a function of reducing reverse current flow from the current diffusion layer 8 side of the compound semiconductor layer 2 toward the functional substrate 3. Further, although the high-resistance layer has a bonding structure that exhibits favorable withstand voltage properties relative to voltages inadvertently applied in the reverse direction from the functional substrate 3 to the current diffusion layer 8, the bonding structure is preferably such that the breakdown voltage is a lower value than the reverse direction voltage for the pn junction-type light-emitting unit 7.

The n-type ohmic electrode (first electrode) 4 and the p-type ohmic electrode (second electrode) 5 are low-resistance ohmic contact electrodes provided on the main light extraction surface of the light-emitting diode 1.

In this embodiment, the n-type ohmic electrode 4 is provided on top of the upper cladding layer 13, and can be formed using AuGe or an alloy composed of a Ni alloy and Au. On the other hand, as illustrated in FIG. 4, the p-type ohmic electrode 5 is formed on the exposed surface of the current diffusion layer 8, and is formed using an alloy composed of AuBe and Au, or AuZn and Au.

In the light-emitting diode 1 of the present embodiment, the p-type ohmic electrode 5 that functions as the second electrode is preferably formed on the current diffusion layer 8. By employing this type of structure, the operating voltage can be reduced. Further, by forming the p-type ohmic electrode 5 on a current diffusion layer 8 formed from p-type GaP, a favorable ohmic contact can be achieved, enabling a further reduction in the operating voltage.

In the present embodiment, the polarity of the first electrode is preferably n-type, and the polarity of the second electrode is preferably p-type. Using this type of structure enables a higher brightness to be achieved for the light-emitting diode 1. On the other hand, if the polarity of the first electrode is p-type, then current diffusion deteriorates and the brightness tends to decrease. In contrast, by making the first electrode an n-type electrode, current diffusion is improved, and improved brightness can be achieved for the light-emitting diode 1.

As illustrated in FIG. 3, in the light-emitting diode 1 of the present embodiment, the n-type ohmic electrode 4 and the p-type ohmic electrode 5 are preferably disposed in diagonally opposing positions. Further, the periphery of the p-type ohmic electrode 5 is most preferably surrounded by the compound semiconductor layer 2. By adopting this type of structure, the operating voltage can be reduced. Further, surrounding the p-type ohmic electrode 5 on all sides with the n-type ohmic electrode 4 facilitates the flow of electric current in all directions, resulting in a reduction in the operating voltage.

Furthermore, as illustrated in FIG. 3, in the light-emitting diode 1 of the present embodiment, the n-type ohmic electrode 4 is preferably formed as a mesh-like structure such as a honeycomb or grid. Adopting this type of structure enables the reliability to be improved. Further, using a grid-like structure enables current to be introduced more uniformly into the active layer 11, resulting in improved reliability. In the light-emitting diode 1 of this embodiment, the n-type ohmic electrode 4 is preferably formed from a pad-shaped electrode (a pad electrode) and a linear electrode with a width of not more than 10 μm (a linear electrode). This type of structure enables higher brightness to be obtained. Moreover, by ensuring a narrow width for the linear electrode, the open surface area of the light extraction surface can be increased, enabling a higher level of brightness to be achieved.

### <Method of Producing Light-Emitting Diode>

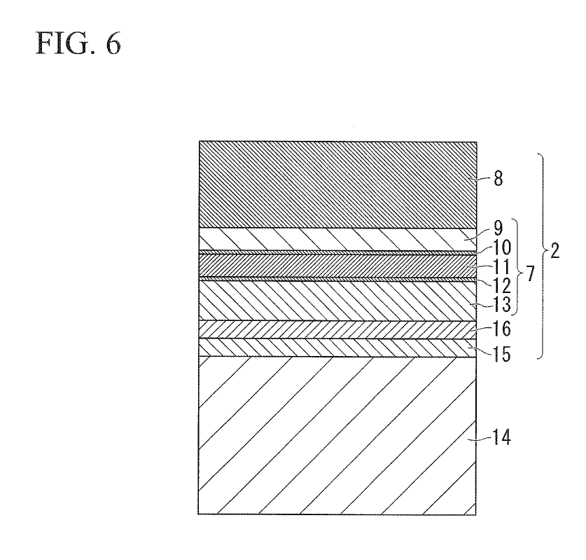

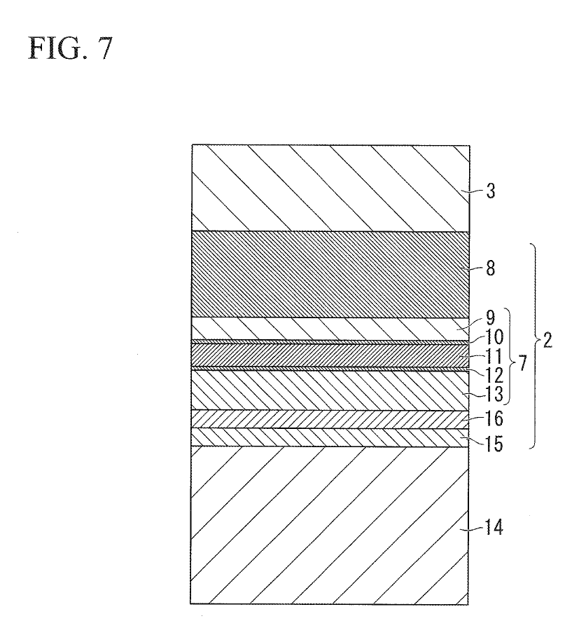

Next is a description of a method of producing the light-emitting diode 1 of the present embodiment. FIG. 6 is a cross-sectional view of an epiwafer used in the light-emitting diode 1 according to the present embodiment. Further, FIG. 7 is a cross-sectional view of a bonded wafer used in the light-emitting diode 1 according to the present embodiment.

### (Compound Semiconductor Layer Formation Step)

First, as illustrated in FIG. 6, the compound semiconductor layer 2 is produced. The compound semiconductor layer 2 is formed by sequentially stacking, on top of a GaAs substrate 14, a buffer layer 15 formed from GaAs, an etching stop layer (not shown in the figure) that is provided to enable the use of selective etching, a contact layer 16 formed from Si-doped n-type AlGaAs, the n-type upper cladding layer 13, the upper guide layer 12, the active layer 11, the lower guide layer 10, the p-type lower cladding layer 9, and the current diffusion layer 8 formed from Mg-doped p-type GaP.

The GaAs substrate 14 may use a commercially available monocrystalline substrate produced using conventional production methods. The surface of the GaAs substrate 14 upon which epitaxial growth is to be performed is preferably smooth. In terms of facilitating epitaxial growth, the planar orientation of the surface of the GaAs substrate 14 is preferably the mass-produced (100) plane and within a range of ±20° off the (100) plane in terms of quality stability. Moreover, the planar orientation of the surface of the GaAs substrate 14 is more preferably 15°±5° off the (100) direction toward the (0-1-1) direction.

In order to improve the crystallinity of the compound semiconductor layer 2, the dislocation density of the GaAs substrate 14 is preferably low. Specifically, the dislocation density is typically not more than 10,000 cm⁻², and is preferably not more than 1,000 cm⁻².

The GaAs substrate 14 may be either an n-type or a p-type substrate. The carrier concentration of the GaAs substrate 14 may be selected as appropriate in order to achieve the desired electrical conductivity and device structure. For example, in the case where the GaAs substrate 14 is a silicon-doped n-type substrate, the carrier concentration is preferably within a range from 1×10¹⁷ to 5×10¹⁸ cm⁻³. In contrast, in the case where the GaAs substrate 14 is a zinc-doped p-type substrate, the carrier concentration is preferably within a range from 2×10¹⁸ to 5×10¹⁹ cm⁻³.

The thickness of the GaAs substrate 14 may be set within an appropriate range in accordance with the substrate size. If the thickness of the GaAs substrate 14 is thinner than this appropriate range, then there is a danger of breakage occurring during the production process for the compound semiconductor layer 2. In contrast, if the thickness of the GaAs substrate 14 is thicker than the appropriate range, then the material costs increase. Accordingly, in those cases where the substrate size of the GaAs substrate 14 is large, for example in the case of a substrate having a diameter of 75 mm, the substrate thickness is preferably within a range from 250 to 500 μm in order to prevent breakage during handling. Similarly, if the diameter of the substrate is 50 mm, then the thickness is preferably within a range from 200 to 400 μm, whereas if the diameter is 100 mm, the thickness is preferably within a range from 350 to 600 μm.

In this mariner, by setting the thickness of the GaAs substrate 14 in accordance with the substrate size, warping of the compound semiconductor layer 2 caused by the active layer 11 can be reduced. As a result, the temperature distribution during epitaxial growth becomes more uniform, meaning the wavelength distribution within the plane of the active layer 11 can be narrowed. The shape of the GaAs substrate 14 is not necessarily limited to circular shapes, and a rectangular shape or the like may also be used without any problems.

The buffer layer 15 is provided to reduce the transmission of defects between the GaAs substrate 14 and the constituent layers of the light-emitting unit 7. Accordingly, provided the substrate quality and the epitaxial growth conditions are selected appropriately, the buffer layer 15 may not be necessary. The material for the buffer layer 15 is preferably the same material as that of the epitaxial growth substrate. In other words, in the present embodiment, the buffer layer 15 preferably employs the same GaAs as the GaAs substrate 14. In order to reduce the transmission of defects, the buffer layer 15 may employ a multilayer film composed of different materials from the GaAs substrate 14. The thickness of the buffer layer 15 is preferably at least 0.1 μm, and is more preferably 0.2 μm or greater.

The contact layer 16 is provided for the purpose of reducing the contact resistance with the electrodes. The material of the contact layer 16 preferably has a larger band gap than that of the active layer 11, and is preferably a material having a composition represented by Al_{X}Ga_{1-X}As or (Al_{X}Ga_{1-X})_{Y}In_{1-Y}P (wherein 0≦X≦1 and 0≦Y≦1). Further, in order to reduce the contact resistance with the electrodes, the lower limit for the carrier concentration within the contact layer 16 is preferably not less than 5×10¹⁷ cm⁻³, and is more preferably 1×10¹⁸ cm⁻³ or greater. The upper limit for the carrier concentration is preferably not more than 2×10¹⁹ cm⁻³, at which point the crystallinity tends to deteriorate. The thickness of the contact layer 16 is preferably at least 0.5 μm, and is most preferably 1 μm or greater. Although there are no particular limitations on the upper limit for the thickness of the contact layer 16, in order to ensure that the costs associated with the epitaxial growth fall within an appropriate range, the thickness is preferably not more than 5 μm.

In the present embodiment, conventional growth methods such as molecular beam epitaxy (MBE) and reduced-pressure metalorganic chemical vapor deposition (MOCVD) may be employed. Of these, the use of the MOCVD method, which offers superior applicability to mass production, is particularly desirable. Specifically, the GaAs substrate 14 used for epitaxial growth of the compound semiconductor layer 2 is preferably first subjected to preliminary treatments such as washing and heating treatments prior to the growing process in order to remove contaminants and any natural oxide film from the substrate surface. The layers that constitute the compound semiconductor layer 2 can be laminated by simultaneous epitaxial growth onto GaAs substrates 14 of diameter 50 to 150 mm positioned inside a MOCVD apparatus. Commercially available large-scale apparatus such as self-rotating or high-speed rotating apparatus can be used as the MOCVD apparatus.

During epitaxial growth of each of the layers of the compound semiconductor layer 2, compounds such as trimethylaluminum ((CH₃)₃Al), trimethylgallium ((CH₃)₃Ga) and trimethylindium ((CH₃)₃In) can be used as the raw materials for the group III elements. Further, bis(cyclopentadienyl)magnesium (bis-(C₅H₅)₂Mg) or the like can be used as a Mg doping raw material. Furthermore, disilane (Si₂H₆) or the like can be used as a Si doping raw material. Moreover, phosphine (PH₃) and arsine (AsH₃) and the like may be used as raw materials for the group V elements. In terms of the growing temperature used for each of the layers, in those cases where a p-type GaP is used as the current diffusion layer 8, growth of the current diffusion layer 8 is typically performed at a temperature within a range from 720 to 770° C., whereas each of the other layers is typically grown at 600 to 700° C. Moreover, the carrier concentration, thickness and temperature conditions for each layer may be selected as appropriate.

The compound semiconductor layer 2 produced in this manner has a favorable surface state with minimal crystal defects, despite including the light-emitting unit 7. Further, depending on the device structure, the compound semiconductor layer 2 may be subjected to surface processing such as polishing or the like.

### (Functional Substrate Bonding Step)

Next, the compound semiconductor layer 2 and the functional substrate 3 are bonded together. When bonding the compound semiconductor layer 2 and the functional substrate 3, first, the surface of the current diffusion layer 8 of the compound semiconductor layer 2 is polished to a mirror finish. Next, the functional substrate 3 that is to be bonded to the mirror-polished surface of the current diffusion layer 8 is prepared. The surface of this functional substrate 3 is polished to a mirror finish prior to bonding to the current diffusion layer 8. Subsequently, the compound semiconductor layer 2 and the functional substrate 3 are installed in a typical semiconductor material bonding apparatus, and the two minor-polished surfaces are irradiated under vacuum conditions with an Ar beam neutralized by bombardment with electrons. Subsequently, with the vacuum conditions maintained inside the bonding apparatus, the two surfaces are brought together and a load is applied, thus enabling bonding to be performed at room temperature (see FIG. 7). For the bonding, in terms of the stability of the bonding conditions, it is preferable that the surfaces undergoing bonding are formed from the same material.

Although the bonding is ideally this type of room temperature bonding performed under vacuum conditions, eutectic metal bonding or bonding using an adhesive may also be employed.

### (First and Second Electrodes Formation Step)

Next, the n-type ohmic electrode 4 that acts as the first electrode and the p-type ohmic electrode 5 that acts as the second electrode are formed. When forming the n-type ohmic electrode 4 and the p-type ohmic electrode 5, first, an ammonia-based etchant is used to selectively remove the GaAs substrate 14 and the buffer layer 15 from the compound semiconductor layer 2 that is bonded to the functional substrate 3. Subsequently, the n-type ohmic electrode 4 is formed on the surface of the exposed contact layer 16. Specifically, for example, a vacuum deposition method is used to deposit a certain thickness of AuGe or Ni alloy/Pt/Au, and a typical photolithography method is then used to pattern the deposited layer to form the shape of the n-type ohmic electrode 4.

Subsequently, portions of the contact layer 16, the upper cladding layer 13, the upper guide layer 12, the active layer 11, the lower guide layer 10 and the p-type lower cladding layer 9 are selectively removed to expose the current diffusion layer 8, and the p-type ohmic electrode 5 is then formed on this exposed surface of the current diffusion layer 8. Specifically, for example, a vacuum deposition method is used to deposit a certain thickness of AuBe/Au, and a typical photolithography method is then used to pattern the deposited layer to form the shape of the p-type ohmic electrode 5. By subsequently performing alloying, by conducting a heat treatment under conditions including a temperature of 400 to 500° C. for a period of 5 to 20 minutes, the low-resistance n-type ohmic electrode 4 and p-type ohmic electrode 5 can be formed.

### (Functional Substrate Processing Step)

Next, the shape of the functional substrate 3 is processed. When processing the functional substrate 3, first, V-shaped slots are formed in the surface of the functional substrate 3 in locations where the third electrode 6 does not exist. The inside surface of the V-shaped slot that faces the third electrode 6 becomes the inclined surface 3b that forms an angle α relative to a surface parallel to the light emission surface. Subsequently, dicing is performed at predetermined intervals from the side of the compound semiconductor layer 2, thus forming chips. The dicing performed during this chipping step forms the vertical surfaces 3a of the functional substrate 3.

There are no particular limitations on the method used for forming the inclined surfaces 3b, and conventional methods such as wet etching, dry etching, scribing or laser processing may be combined as appropriate, although the use of a dicing method, which offers high levels of shape controllability and productivity, is the most desirable. By employing a dicing method, the production yield can be increased.

Further, although there are no particular limitations on the method used for forming the vertical surfaces 3a, a laser processing method, a scribe-break method or a dicing method is preferred. Employing a laser processing method or a scribe-break method enables the production costs to be reduced. In other words, a reserve for cutting need not be provided during chip separation, meaning a larger number of light-emitting diodes can be produced, thus reducing production costs. On the other hand, a dicing method offers excellent cutting stability.

Finally, if necessary, any fractured layers or soiling may be removed by etching with a mixed liquid of sulfuric acid and hydrogen peroxide or the like. This completes the production of the light-emitting diode 1.

### <Method of Producing Light-Emitting Diode Lamp>

Next is a description of a method of producing a light-emitting diode lamp 41 using the light-emitting diode 1 described above, namely, a method of mounting the light-emitting diode 1.

As illustrated in FIG. 1 and FIG. 2, a predetermined number of the light-emitting diodes 1 are mounted on the surface of the mounting substrate 42. When mounting the light-emitting diode 1, the mounting substrate 42 and the light-emitting diode 1 are first positioned relative to each other, and the light-emitting diode 1 is placed in a predetermined position on the mounting substrate 42. Next, die bonding is performed using an Ag paste, thus securing the light-emitting diode 1 to the surface of the mounting substrate 42. The n-type ohmic electrode 4 of the light-emitting diode 1 and the n-electrode terminal 43 of the mounting substrate 42 are then connected using the gold wire 45 (wire bonding). Next, the p-type ohmic electrode 5 of the light-emitting diode 1 and the p-electrode terminal 44 of the mounting substrate 42 are connected using the gold wire 46. Finally, the surface of the mounting substrate 42 on which the light-emitting diode 1 is mounted is sealed with a typical sealing resin 47 such as a silicon resin or an epoxy resin. This completes production of the light-emitting diode lamp 41 using the light-emitting diode 1.

Because the composition of the active layer 11 has been adjusted, the emission spectrum of the light-emitting diode lamp 41 has a peak emission wavelength within the range from 660 to 850 nm. Further, because the current diffusion layer 8 suppresses fluctuation of the well layer 17 and the barrier layer 18 within the active layer 11, the full width at half maximum of the emission spectrum is within a range from 10 to 40 nm.

As described above, the light-emitting diode 1 of the present embodiment includes a compound semiconductor layer 2 that contains the light-emitting unit 7 having the well layer 17 formed from (Al_{X1}Ga_{1-X1})As (wherein 0≦X1≦1).

Further, in the light-emitting diode 1 of the present embodiment, the current diffusion layer 8 is provided on the light-emitting unit 7. This current diffusion layer 8 is transparent to the emission wavelength, and therefore a high-output, high-efficiency light-emitting diode 1 can be produced that does not absorb the light emitted from the light-emitting unit 7. The functional substrate is materially stable, and exhibits excellent moisture resistance, with no concern of corrosion.

Accordingly, by appropriate adjustment of the conditions for the active layer, the light-emitting diode 1 of the present embodiment is able to provide a moisture-resistant light-emitting diode 1 which has an emission wavelength of 660 to 850 nm, excellent monochromaticity, and also exhibits high output and high efficiency. Further, the light-emitting diode 1 of the present embodiment is able to provide a high-output infrared light-emitting diode 1 having an emission output that is at least 1.5 times the output of a conventional transparent substrate-type AlGaAs-based light-emitting diode produced by conventional liquid phase epitaxial methods and subsequent removal of the GaAs substrate.

Furthermore, the light-emitting diode lamp 41 of the present embodiment includes the aforementioned moisture-resistant light-emitting diode 1 which has excellent monochromaticity and also exhibits high output and high efficiency. As a result, a light-emitting diode lamp 41 can be provided that is ideal for infrared illumination or for use as a sensor.

### <Light-Emitting Diode (Second Embodiment)>

A light-emitting diode according to a second embodiment of the present invention differs from the first embodiment in that the AlGaAs barrier layer 18 in the light-emitting diode according to the first embodiment is replaced with a barrier layer formed from a compound semiconductor having a composition formula of (Al_{X3}Ga_{1-X3})_{Y2}In_{1-Y2}P (wherein 0≦X3≦1 and 0≦Y2≦1).

The barrier layer is formed from a compound semiconductor having a composition formula represented by (Al_{X3}Ga_{1-X3})_{Y2}In_{1-Y2}P (wherein 0≦X3≦1 and 0≦Y2≦1).

The Al composition X3 is preferably set so as to achieve a composition that has a larger band gap than that of the well layer, and specifically, is preferably within a range from 0 to 0.2.

Further, in terms of preventing strain caused by lattice mismatching with the substrate, Y2 is preferably within a range from 0.4 to 0.6, and is more preferably from 0.45 to 0.55.

The thickness of the barrier layer is preferably either equal to the thickness of the well layer, or thicker than the thickness of the well layer.

By ensuring an adequate thickness within the range in which tunneling effects occur, diffusion between well layers caused by tunneling can be suppressed, and the carrier confinement effect can be enhanced, thereby increasing the probability of emissive recombination of electrons and electron holes, resulting in an improved emission output.

### <Light-Emitting Diode (Third Embodiment)>

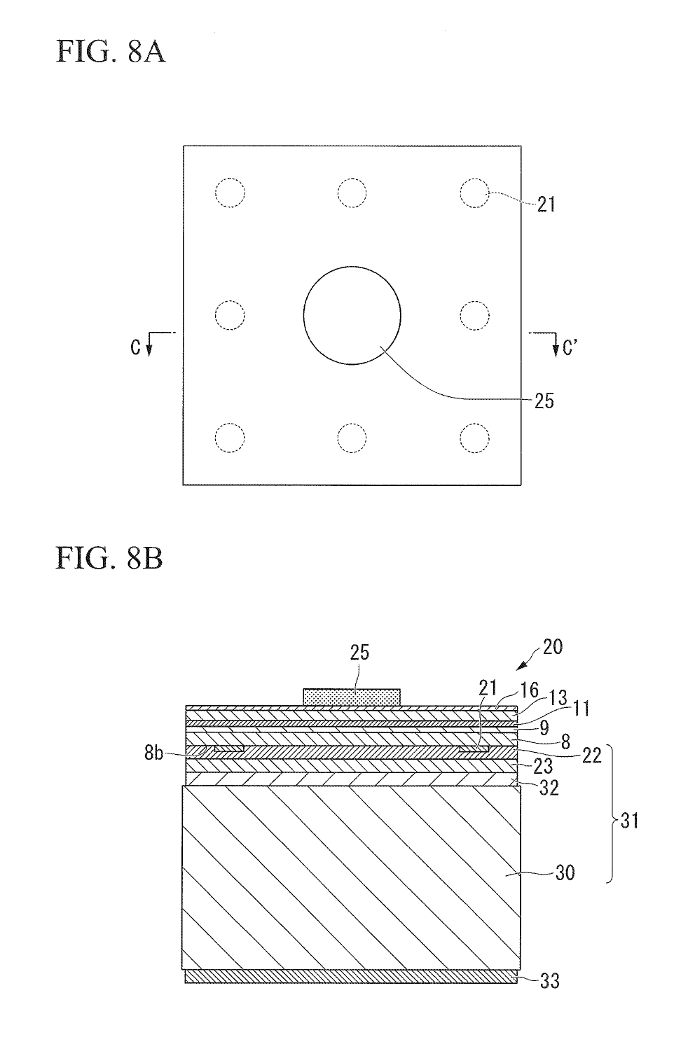

FIG. 8A and FIG. 8B are diagrams for describing a light-emitting diode according to a third embodiment of the present invention, wherein FIG. 8A is a plan view, and FIG. 8B is a cross-sectional view along the line C-C in FIG. 8A.

A light-emitting diode 20 according to the third embodiment includes a light-emitting unit, containing an active layer 11 having a quantum well structure formed by alternately stacking a well layer and a barrier layer each formed from a compound semiconductor having a composition formula of (Al_{X1}Ga_{1-X1})As (wherein 0≦X1≦1), and a first cladding layer 9 and a second cladding layer 13 that sandwich the active layer 11, a current diffusion layer 8 formed on the light-emitting unit, and a functional substrate 31, which contains a reflective layer 23 that is disposed facing the light-emitting unit and has a reflectance of at least 90% relative to the emission wavelength, and which is bonded to the current diffusion layer 8, wherein the first and second cladding layers are formed from a compound semiconductor having a composition formula of (Al_{X2}Ga_{1-X2})_{Y1}In_{1-Y1}P (wherein 0≦X2≦1 and 0≦Y1≦1), and the number of pairs of the well layer and the barrier layer is not more than five.

The light-emitting diode 20 according to the third embodiment has the functional substrate 31, which is provided with the reflective layer 23 that has a reflectance of at least 90% relative to the emission wavelength and is disposed facing the light-emitting unit, and therefore light can be extracted efficiently from the main light extraction surface.

In the example illustrated in FIG. 8B, the functional substrate 31 has a second electrode 21 provided on the lower surface 8b of the current diffusion layer 8, and also has a reflective structure, prepared by stacking a transparent conductive film 22 and the reflective layer 23 so as to cover the second electrode 21, and a layer (substrate) 30 formed from silicon or germanium. Further, a first electrode 25 is formed on top of the contact layer 16 formed on the upper surface of the second cladding layer 13.

In the light-emitting diode according to the third embodiment, the functional substrate 31 preferably includes a layer formed from silicon or germanium. Because these materials are resistant to corrosion, including such a layer improves the moisture resistance.

The reflective layer 23 is composed of silver (Ag), aluminum (Al), gold (Au), or an alloy of these metals. These materials have excellent optical reflectance, enabling an optical reflectance of at least 90% to be achieved from the reflective layer 23.

In the functional substrate 31, the reflective layer 23 can use a combination prepared by bonding a eutectic metal such as AuIn, AuGe or AuSn to an inexpensive substrate (layer) such as silicon or germanium. In particular, AuIn has a low bonding temperature, and although the coefficient of thermal expansion differs from that of the light-emitting unit, it is ideal for bonding the cheapest silicon substrate (silicon layer).

In order to prevent mutual diffusion between the current diffusion layer, the reflective layer metal and the eutectic metal, adopting a structure for the functional substrate 31 that also includes an inserted layer formed from a high-melting point metal such as titanium (Ti), tungsten (W) or platinum (Pt) is desirable in terms of ensuring good quality stability.

### <Light-Emitting Diode (Fourth Embodiment)>

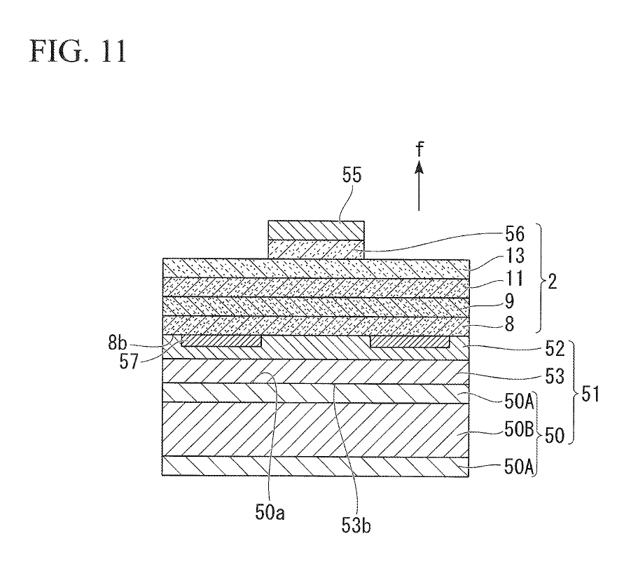

FIG. 11 is a diagram describing a light-emitting diode according to a fourth embodiment of the present invention.

A light-emitting diode according to the fourth embodiment of the present invention includes a light-emitting unit, containing an active layer 11 having a quantum well structure formed by alternately stacking a well layer and a barrier layer each formed from a compound semiconductor having a composition formula of (Al_{X1}Ga_{1-X1})As (wherein 0≦X1≦1), and a first cladding layer 9 and a second cladding layer 13 that sandwich the active layer, a current diffusion layer 8 formed on the light-emitting unit, and a functional substrate 51, which contains a reflective layer 53 that is disposed facing the light-emitting unit and has a reflectance of at least 90% relative to the emission wavelength and a metal substrate 50, and which is bonded to the current diffusion layer 8, wherein the first and second cladding layers 9 and 13 are formed from a compound semiconductor having a composition formula of (Al_{X2}Ga_{1-X2})_{Y1}In_{1-Y1}P (wherein 0≦X2≦1 and 0≦Y1≦1), and the number of pairs of the well layer and the barrier layer is not more than five.

In the light-emitting diode according to the fourth embodiment, the fact that the functional substrate includes a metal substrate is the feature that distinguishes this light-emitting diode from the light-emitting diode according to the third embodiment.

The metal substrate exhibits excellent heat dissipation properties, and not only contributes to high-brightness emission from the light-emitting diode, but is able to extend the lifespan of the light-emitting diode.

From the viewpoint of the heat dissipation properties, the metal substrate is preferably formed from a metal having a thermal conductivity of at least 130 W/m·K. Examples of metals having a thermal conductivity of at least 130 W/m·K include molybdenum (138 W/m·K) and tungsten (174 W/m·K).

As illustrated in FIG. 11, the compound semiconductor layer 2 includes the active layer 11, the first cladding layer (lower cladding layer) 9 and the second cladding layer (upper cladding layer) 13 that sandwich the active layer 11 via guide layers (not shown in the drawing), the current diffusion layer 8 provided on the lower surface of the first cladding layer (lower cladding layer) 9, and a first electrode 55 and a contact layer 56 of substantially the same size as the first electrode when viewed in plan view provided on the upper surface of the second cladding layer (upper cladding layer) 13. The contact layer 56 may also be formed across the entire surface of the second cladding layer (upper cladding layer) 13, in the same manner as the contact layer illustrated in FIG. 8B.

A functional substrate 51 is composed of a second electrode 57 provided on the lower surface 8b of the current diffusion layer 8, a reflective structure prepared by stacking a transparent conductive film 52 and a reflective layer 53 so as to cover the second electrode 57, and a metal substrate 50, wherein a bonding surface 50a of the metal substrate 50 is bonded to the surface 53b of the reflective layer 53 of the reflective structure on the opposite side to the compound semiconductor layer 2.

The reflective layer 53 is formed from a metal such as copper, silver, gold or aluminum, or from an alloy of these metals. These materials exhibit a high degree of optical reflectance, enabling a reflectance of 90% or higher to be achieved from the reflective structure. By forming this type of reflective layer 53, light from the active layer 11 is reflected off the reflective layer 53 in the front direction f, meaning the light extraction efficiency in the front direction f can be improved. As a result, the brightness of the light-emitting diode can be increased.

The reflective layer 53 preferably has a stacked structure composed of Ag, a Ni/Ti barrier layer, and an Au-based eutectic metal (connection metal) from the side of the transparent conductive film 52.

The aforementioned connection metal is a metal having low electrical resistance and a low melting point. By using this type of connection metal, the metal substrate can be connected without imparting heat stress to the compound semiconductor layer 2.

An Au-based eutectic metal or the like, which is chemically stable and has a low melting point, can be used as the connection metal. Specific examples of this type of Au-based eutectic metal include eutectic compositions of alloys such as AuSn, AuGe and AuSi (namely, Au-based eutectic metals).

Further, it is desirable that a metal such as titanium, chromium or tungsten is added to the connection metal. This enables the metal such as titanium, chromium or tungsten to function as a barrier metal, thereby inhibiting the diffusion and subsequent reaction of impurities or the like from the metal substrate into the reflective layer 53 side of the structure.

The transparent conductive film 52 may be formed from an ITO film or an IZO film or the like. Alternatively, the reflective structure may be composed of only the reflective layer 53.

Further, a so-called cold mirror that utilizes the difference in refractive index between transparent materials, such as a multilayer film of titanium oxide and silicon oxide, or white alumina or AlN, may be used instead of the transparent conductive film 52, or together with the transparent conductive film 52, in combination with the reflective layer 53.

The metal substrate 50 can use a substrate composed of a plurality of metal layers. The metal substrate preferably has a structure in which two different types of metal layer are stacked in an alternating arrangement.

It is particularly desirable that the total number of layers of the two types of metal layer is an odd number.

In such cases, from the viewpoint of warping and cracking of the metal substrate, when a material having a smaller coefficient of thermal expansion than the compound semiconductor layer 2 is used as a second metal layer 50B, it is preferable that a material having a larger coefficient of thermal expansion than the compound semiconductor layer 2 is used for first metal layers 50A and 50A. This ensures that the overall coefficient of thermal expansion for the entire metal substrate is similar to the coefficient of thermal expansion of the compound semiconductor layer, and can therefore inhibit warping or cracking of the metal substrate when the compound semiconductor layer and the metal substrate are bonded together, thereby increasing the production yield of the light-emitting diode. Similarly, when a material having a larger coefficient of thermal expansion than the compound semiconductor layer 2 is used as the second metal layer 50B, it is preferable that a material having a smaller coefficient of thermal expansion than the compound semiconductor layer 2 is used for the first metal layers 50A and 50A. This ensures that the overall coefficient of thermal expansion for the entire metal substrate is similar to the coefficient of thermal expansion of the compound semiconductor layer, and can therefore inhibit warping or cracking of the metal substrate when the compound semiconductor layer and the metal substrate are bonded together, thereby increasing the production yield of the light-emitting diode.

As is evident from the description above, it does not matter which of the two types of metal layer is used as the first metal layer and which is used as the second metal layer.

Examples of the two types of metal layer include a combination of a metal layer formed from any one of silver (coefficient of thermal expansion=18.9 ppm/K), copper (coefficient of thermal expansion=16.5 ppm/K), gold (coefficient of thermal expansion=14.2 ppm/K), aluminum (coefficient of thermal expansion=23.1 ppm/K), nickel (coefficient of thermal expansion=13.4 ppm/K) and an alloy of these metals, and a metal layer formed from any one of molybdenum (coefficient of thermal expansion=5.1 ppm/K), tungsten (coefficient of thermal expansion=4.3 ppm/K), chromium (coefficient of thermal expansion=4.9 ppm/K) and an alloy of these metals.

A preferred example is a metal substrate having a three-layer structure composed of Cu/Mo/Cu. As described above, a metal substrate having a three-layer structure composed of Mo/Cu/Mo layer yields a similar effect, but because a metal substrate having a three-layer structure composed of Cu/Mo/Cu has a structure in which the Mo, which has a high degree of mechanical strength, is sandwiched between the readily worked Cu, this particular structure offers the advantage of providing easier processing such as cutting of the metal substrate than the metal substrate having a three-layer structure composed of Mo/Cu/Mo.

The overall coefficient of thermal expansion for the entire metal substrate is 6.1 ppm/K in the case where the metal substrate has a three-layer structure composed of Cu (30 μm)/Mo (25 μm)/Cu (30 μm), and is 5.7 ppm/K in the case where the metal substrate has a three-layer structure composed Mo (25 μm)/Cu (70 μm)/Mo (25 μm).

Further, from the viewpoint of heat dissipation, the metal layers that constitute the metal substrate are preferably composed of materials having a high degree of thermal conductivity. By using such materials, the heat dissipation properties of the metal substrate can be improved, meaning that not only can the light-emitting diode emit at a high brightness level, but the lifespan of the light-emitting diode can be extended.

For example, the use of silver (thermal conductivity=420 W/m·K), copper (thermal conductivity=398 W/m·K), gold (thermal conductivity=320 W/m·K), aluminum (thermal conductivity=236 W/m·K), molybdenum (thermal conductivity=138 W/m·K), tungsten (thermal conductivity=174 W/m·K), and alloys of these metals. is particularly desirable.

It is preferable that the coefficient of thermal expansion of the metal layers is approximately equal to the coefficient of thermal expansion of the compound semiconductor layer. It is particularly desirable that the coefficient of thermal expansion of the materials of the metal layers is within ±1.5 ppm/K of the coefficient of thermal expansion of the compound semiconductor layer. This enables the heat stress that is generated within the light-emitting unit when the metal substrate and the compound semiconductor layer are bonded together to be minimized, and therefore cracking of the metal substrate caused by the heat used when the metal substrate and the compound semiconductor layer are bonded can be inhibited, thus enabling the production yield of the light-emitting diode to be increased.

The thermal conductivity of the entire metal substrate is 250 W/m·K in the case where the metal substrate has a three-layer structure composed of Cu (30 μm)/Mo (25 μm)/Cu (30 μm), and is 220 W/m·K in the case where the metal substrate has a three-layer structure composed Mo (25 μm)/Cu (70 μm)/Mo (25 μm).

### <Light-Emitting Diode (Fifth Embodiment)>

A light-emitting diode according to a fifth embodiment of the present invention includes a light-emitting unit, containing an active layer having a quantum well structure prepared by alternately stacking a well layer formed from a compound semiconductor having a composition formula of (Al_{X1}Ga_{1-X1})As (wherein 0≦X1≦1) and a barrier layer formed from a compound semiconductor having a composition formula of (Al_{X3}Ga_{1-X3})_{Y2}In_{1-Y2}P (wherein 0≦X3≦1 and 0≦Y2≦1), and a first cladding layer and a second cladding layer that sandwich the active layer, a current diffusion layer formed on the light-emitting unit, and a functional substrate, which contains a reflective layer that is disposed facing the light-emitting unit and has a reflectance of at least 90% relative to the emission wavelength, and which is bonded to the current diffusion layer, wherein the first and second cladding layers are formed from a compound semiconductor having a composition formula of (Al_{X2}Ga_{1-X2})_{Y1}In_{1-Y1}P (wherein 0≦X2≦1 and 0≦Y1≦1), and the number of pairs of the well layer and the barrier layer is not more than five.

The light-emitting diode according to the fifth embodiment is the same as the light-emitting diode according to the third embodiment, with the exception that the AlGaAs barrier layer of the third embodiment has been replaced with a barrier layer formed from a compound semiconductor having a composition formula of (Al_{X3}Ga_{1-X3})_{Y2}In_{1-Y2}P (wherein 0≦X3≦1 and 0≦Y2≦1).

The barrier layer is formed from a compound semiconductor represented by the composition formula (Al_{X3}Ga_{1-X3})_{Y2}In_{1-Y2}P (wherein 0≦X3≦1 and 0≦Y2≦1).

The Al composition X3 is preferably set so as to achieve a composition that has a larger band gap than that of the well layer, and specifically, is preferably within a range from 0 to 0.2.

Further, in terms of preventing strain caused by lattice mismatching with the substrate, Y2 is preferably within a range from 0.4 to 0.6, and is more preferably from 0.45 to 0.55.

The thickness of the barrier layer is preferably either equal to the thickness of the well layer, or thicker than the thickness of the well layer.

By ensuring an adequate thickness within the range in which tunneling effects occur, diffusion between well layers caused by tunneling can be suppressed, and the carrier confinement effect can be enhanced, thereby increasing the probability of emissive recombination of electrons and electron holes, resulting in an improved emission output.

In a similar manner to the third embodiment, the light-emitting diode according to this embodiment has a functional substrate which is provided with a reflective layer that has a reflectance of at least 90% relative to the emission wavelength and is disposed facing the light-emitting unit, and therefore light can be extracted efficiently from the main light extraction surface.

Further, in this embodiment, the same substrates as those described above for the third embodiment can be used as the functional substrate.

### <Light-Emitting Diode (Sixth Embodiment)>

A light-emitting diode according to a sixth embodiment of the present invention includes a light-emitting unit, containing an active layer having a quantum well structure prepared by alternately stacking a well layer formed from a compound semiconductor having a composition formula of (Al_{X1}Ga_{1-X1})As (wherein 0≦X1≦1) and a barrier layer formed from a compound semiconductor having a composition formula of (Al_{X3}Ga_{1-X3})_{Y2}In_{1-Y2}P (wherein 0≦X3≦1 and 0≦Y2≦1), and a first cladding layer and a second cladding layer that sandwich the active layer, a current diffusion layer formed on the light-emitting unit, and a functional substrate, which contains a reflective layer that is disposed facing the light-emitting unit and has a reflectance of at least 90% relative to the emission wavelength and a metal substrate, and which is bonded to the current diffusion layer, wherein the first and second cladding layers are formed from a compound semiconductor having a composition formula of (Al_{X2}Ga_{1-X2})_{Y1}In_{1-Y1}P (wherein 0≦X2≦1 and 0≦Y1≦1), and the number of pairs of the well layer and the barrier layer is not more than five.

The light-emitting diode according to the sixth embodiment is the same as the light-emitting diode according to the fourth embodiment, with the exception that the AlGaAs barrier layer of the fourth embodiment ha been replaced with a barrier layer formed from a compound semiconductor having a composition formula of (Al_{X3}Ga_{1-X3})_{Y2}In_{1-Y2}P (wherein 0≦X3≦1 and 0≦Y2≦1).

In a similar manner to the third embodiment, the light-emitting diode according to this embodiment has a functional substrate which is provided with a reflective layer that has a reflectance of at least 90% relative to the emission wavelength and is disposed facing the light-emitting unit, and therefore light can be extracted efficiently from the main light extraction surface.

Further, in this embodiment, the same substrates as those described above for the fourth embodiment can be used as the functional substrate.

### EXAMPLES

The effects of the present invention are described below in further detail using a series of examples. However, the present invention is in no way limited by these examples. Additions, omissions, substitutions, and other modifications can be made without departing from the spirit or scope of the present invention.

In the examples, light-emitting diodes were produced by bonding together compound semiconductor layers and functional substrates, light-emitting diode lamps were produced for the purposes of evaluating various properties, and these property evaluations were then performed.

### Example 1

The light-emitting diode of Example 1 is an example of the first embodiment, wherein the junction area between the active layer and each of the cladding layers was 123,000 μm² (350 μm×350 μm).

First, an epitaxial wafer having an emission wavelength of 730 nm was produced by sequentially stacking compound semiconductor layers on top of a GaAs substrate composed of monocrystalline Si-doped n-type GaAs. In the GaAs substrate, the growth plane was inclined 15° from the (100) plane toward the (0-1-1) direction, and the carrier concentration was 2×10¹⁸ m⁻³. The thickness of the GaAs substrate was approximately 0.5 μm. The compound semiconductor layers included an n-type buffer layer formed from Si-doped GaAs, an n-type contact layer formed from Si-doped (Al_{0.7}Ga_{0.3})_{0.5}In_{0.5}P, an n-type upper cladding layer formed from Si-doped (Al_{0.7}Ga_{0.3})_{0.5}In_{0.5}P, an upper guide layer formed from Al_{0.4}Ga_{0.6}As, a well layer/barrier layer pair formed from Al_{0.17}Ga_{0.83}As/Al_{0.3}Ga_{0.7}As, a lower guide layer formed from Al_{0.4}Ga_{0.6}As, a p-type lower cladding layer formed from Mg-doped (Al_{0.7}Ga_{0.3})_{0.5}In_{0.5}P, a thin-film intermediate layer formed from (Al_{0.5}Ga_{0.5})_{0.5}In_{0.5}P, and a current diffusion layer formed from Mg-doped p-type GaP.

In this example, a reduced-pressure metalorganic chemical vapor deposition apparatus (MOCVD apparatus) was used, and an epitaxial wafer was formed by performing epitaxial growth of the compound semiconductor layers on a GaAs substrate having a diameter of 76 mm and a thickness of 350 μm. During growth of the epitaxial growth layers, trimethylaluminum ((CH₃)₃Al), trimethylgallium ((CH₃)₃Ga) and trimethylindium ((CH₃)₃In) were used as the raw materials for the group III elements. Further, bis(cyclopentadienyl)magnesium (bis-(C₅H₅)₂Mg) was used as the Mg doping raw material. Furthermore, disilane (Si₂H₆) was used as the Si doping raw material. Moreover, phosphine (PH₃) and arsine (AsH₃) were used as the raw materials for the group V elements. In terms of the growing temperature used for each of the layers, growth of the current diffusion layer formed from p-type GaP was performed at 750° C., whereas each of the other layers was grown at 700° C.

The buffer layer formed from GaAs had a carrier concentration of approximately 2×10¹⁸ cm⁻³ and a thickness of approximately 0.5 μm. The contact layer had a carrier concentration of approximately 2×10¹⁸ cm⁻³ and a thickness of approximately 3.5 μm. The upper cladding layer had a carrier concentration of approximately 1×10¹⁸ m⁻³ and a thickness of approximately 0.5 μm. The upper guide layer was undoped and had a thickness of approximately 50 nm. The well layer was undoped and was formed from a layer of Al_{0.17}Ga_{0.83}As having a thickness of approximately 7 nm, whereas the barrier layer was undoped and was formed from a layer of Al_{0.3}Ga_{0.7}As having a thickness of approximately 19 nm. Further the number of pairs of the well layer and the barrier layer was specified as one pair. The lower guide layer was undoped and had a thickness of approximately 50 nm. The lower cladding layer had a carrier concentration of approximately 8×10¹⁷ cm⁻³ and a thickness of approximately 0.5 μm. The intermediate layer had a carrier concentration of approximately 8×10¹⁷ cm⁻³ and a thickness of approximately 0.05 μm. The current diffusion layer formed from GaP had a carrier concentration of approximately 3×10¹⁸ cm⁻³ and a thickness of approximately 9 μm.

Next, the current diffusion layer was polished down to a depth of approximately 1 μm from the surface, forming a mirror finish. This mirror finishing reduced the surface roughness of the current diffusion layer to 0.18 nm. Meanwhile, the functional substrate formed from n-type GaP was prepared for subsequent bonding to this mirror-polished surface of the current diffusion layer. Si was added to this functional substrate for bonding in an amount sufficient to yield a carrier concentration of approximately 2×10¹⁷ cm⁻³, and a monocrystalline substrate with a planar orientation of (111) was used. The diameter of the functional substrate was 76 mm, and the thickness was 250 μm. Prior to bonding to the current diffusion layer, the surface of this functional substrate was polished to a mirror finish with a root mean square (rms) value of 0.12 nm.

Next, the aforementioned functional substrate and epitaxial wafer were installed in a typical semiconductor material bonding apparatus, and the inside of the apparatus was evacuated down to a vacuum of 3×10⁻⁵ Pa.

Subsequently, the surfaces of both the functional substrate and the current diffusion layer were irradiated for a period of 3 minutes with an Ar beam neutralized by bombardment with electrons. The vacuum conditions were then maintained inside the bonding apparatus, while the surfaces of the functional substrate and the current diffusion layer were brought together. A load was applied that produced a pressure of 50 g/cm² at each of the surfaces, thus bonding the two surfaces together at room temperature. This completed the formation of a bonded wafer.

Next, the GaAs substrate and the GaAs buffer layer were selectively removed from the bonded wafer using an ammonia-based etchant. Subsequently, a first electrode was formed on the surface of the contact layer by using a vacuum deposition method to deposit an AuGe and Ni alloy film having a thickness of 0.5 μm, 0.2 μm of Pt, and then 1 μm of Au. Patterning was then performed using a typical photolithography method, thus forming an n-ohmic electrode as the first electrode. Next, a surface roughening treatment was performed on the surface of the light extraction surface, namely the surface from which the GaAs had been removed.

Next, the epitaxial layers were removed selectively from a region in which a p-type ohmic electrode was to be formed as the second electrode, thus exposing the current diffusion layer. A vacuum deposition method was then used to deposit 0.2 μm of AuBe and 1 μm of Au on the surface of the exposed current diffusion layer, thus forming a p-ohmic electrode. Subsequently, alloying was performed by conducting a heat treatment at 450° C. for 10 minutes, thus completing formation of low-resistance p-type and n-type ohmic electrodes.

Next, a third electrode formed from a film of Au having a thickness of 0.2 μm and a size of 230 μm×230 μm was formed on the functional substrate.

Next, a dicing saw was used to cut V-shaped slots in those regions on the back surface of the functional substrate in which the third electrode was not formed, with the dimensions of the V-shaped slots set so as to yield an angle α for the inclined surfaces of 70° and a vertical surface thickness of 130 μm. Subsequently, a dicing saw was used to cut the structure from the side of the compound semiconductor layer at intervals of 350 μm, thus forming a series of chips. Fractured layers and soiling caused by the dicing were removed by etching using a mixed solution of sulfuric acid and hydrogen peroxide, thus completing preparation of light-emitting diodes of Example 1.

One hundred light-emitting diode lamps were assembled, with each lamp prepared by mounting a light-emitting diode chip of Example 1, prepared in the manner described above, on a mounting substrate. Each of these light-emitting diode lamps was assembled by supporting (mounting) the light-emitting diode chip on the mounting substrate using a die bonder, wire bonding the n-type ohmic electrode of the light-emitting diode to the n-electrode terminal provided on the surface of the mounting substrate using a gold wire, wire bonding the p-type ohmic electrode to the p-electrode terminal using a gold wire, and then sealing the lamp with a typical epoxy resin.

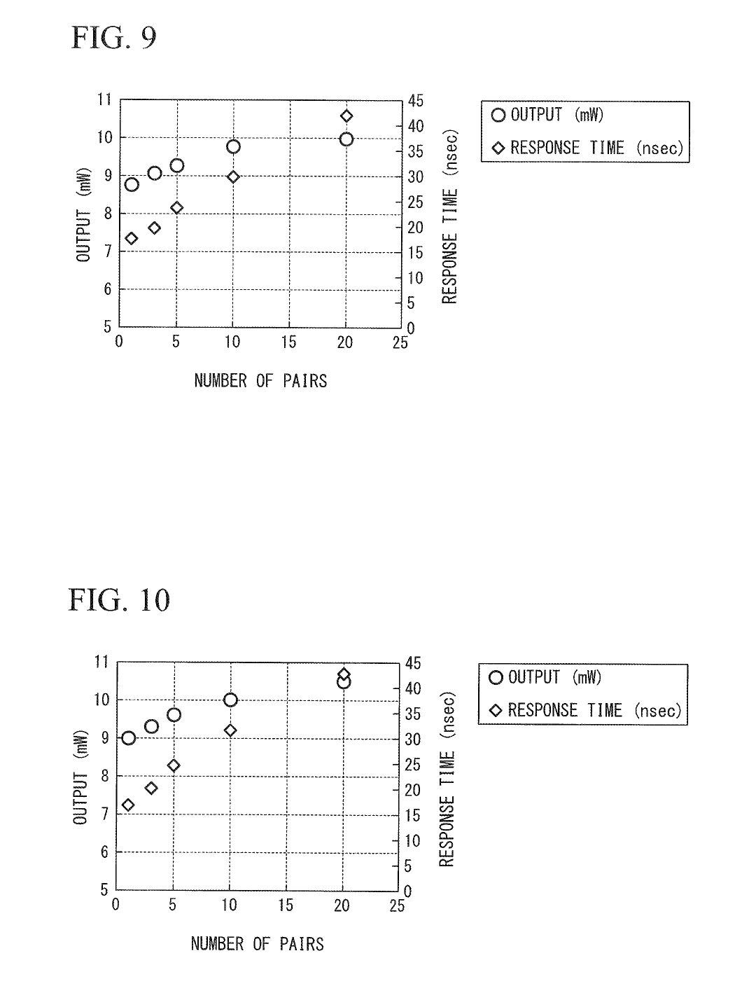

The results of evaluating the properties of these light-emitting diodes (light-emitting diode lamps) are shown in Table 6, FIG. 9 and FIG. 10. FIG. 9 is a graph illustrating the relationship between the number of pairs and the output and response time of the light-emitting diode for the case where the junction area between the active layer and each cladding layer was 123,000 μm². FIG. 10 is a graph illustrating the relationship between the number of pairs and the output and response time of the light-emitting diode for the case where the junction area between the active layer and each cladding layer was 53,000 μm².

As is evident from Table 6, in the first Example, when a current was passed between the n-type and p-type ohmic electrodes, red light having a peak emission wavelength of 730 nm was emitted. The forward voltage (V_{F}) observed when an electric current of 20 milliamperes (mA) flowed though the device in the forward direction was 2.0 volts (V), reflecting the low resistance at the bonding interface between the current diffusion layer of the compound semiconductor layer and the functional substrate, and the favorable ohmic properties of each of the ohmic electrodes. The response time (rise time) (tr) and the emission output (P₀) when the forward current was 20 mA were 18 nsec and 8.8 mW respectively.

TABLE 6

| | Device | | Junction area | Barrier | Number | tr | P₀ | V_{F} |
|---|---|---|---|---|---|---|---|---|
| | structure | Substrate | (μm²) | layer | of pairs | (nsec) | (20 mA) | (20 mA) |
| Example 1 | transparent | GaP | 123,000 | AlGaAs | 1 | 18 | 8.8 | 2.0 |
| Example 2 | transparent | GaP | 123,000 | AlGaAs | 1 | 20 | 9.1 | 2.0 |
| Example 3 | transparent | GaP | 123,000 | AlGaAs | 5 | 24 | 9.3 | 2.0 |
| Example 4 | transparent | GaP | 53,000 | AlGaAs | 1 | 15 | 9.0 | 2.0 |
| Example 5 | transparent | GaP | 53,000 | AlGaAs | 3 | 18 | 9.3 | 2.0 |
| Example 6 | transparent | GaP | 53,000 | AlGaAs | 5 | 22 | 9.6 | 2.0 |
| Example 7 | transparent | GaP | 20,000 | AlGaAs | 5 | 17 | 9.6 | 2.1 |
| Example 8 | transparent | GaP | 90,000 | AlGaAs | 5 | 23 | 9.4 | 2.0 |
| Example 9 | transparent | GaP | 123,000 | AlGaInP | 5 | 24 | 9.0 | 2.1 |
| Example 10 | transparent | GaP | 53,000 | AlGaInP | 1 | 19 | 9.0 | 2.1 |
| Example 11 | reflective | Si | 123,000 | AlGaAs | 5 | 25 | 8.6 | 2.0 |
| Example 12 | reflective | Si | 53,000 | AlGaAs | 3 | 18 | 8.5 | 2.0 |
| Example 13 | reflective | Si | 123,000 | AlGaInP | 5 | 25 | 8.0 | 2.1 |
| Example 14 | reflective | Si | 53,000 | AlGaInP | 3 | 19 | 8.0 | 2.1 |
| Example 15 | reflective | metal | 123,000 | AlGaAs | 5 | 25 | 8.6 | 2.0 |
| Example 16 | reflective | metal | 123,000 | AlGaInP | 5 | 25 | 8.0 | 2.1 |
| Comparative | liquid phase | AlGaAs | | AlGaAs | | 25 | 3.0 | 1.9 |
| example 1 | epitaxy | | | | | | | |
| Reference | transparent | GaP | 123,000 | AlGaAs | 10 | 30 | 9.8 | 2.0 |
| Example 1 | | | | | | | | |
| Reference | transparent | GaP | 123,000 | AlGaAs | 20 | 42 | 10.0 | 2.0 |
| Example 2 | | | | | | | | |
| Reference | transparent | GaP | 53,000 | AlGaAs | 10 | 28 | 10.0 | 2.0 |
| Example 3 | | | | | | | | |
| Reference | transparent | GaP | 53,000 | AlGaAs | 20 | 38 | 10.5 | 2.0 |
| Example 4 | | | | | | | | |

### Example 2

The light-emitting diode of Example 2 is an example of the first embodiment, and with the exception of altering the number of pairs of the well layer and the barrier layer to three pairs, was produced and evaluated under the same conditions as those described for Example 1.

The response time (tr), the emission output (P₀) and the forward voltage (V_{F}) were 20 nsec, 9.1 mW, and 2.0 V respectively.

### Example 3

The light-emitting diode of Example 3 is an example of the first embodiment, and with the exception of altering the number of pairs of the well layer and the barrier layer to five pairs, was produced and evaluated under the same conditions as those described for Example 1.

The response time (tr), the emission output (P₀) and the forward voltage (V_{F}) were 24 nsec, 9.3 mW, and 2.0 V respectively.

The light-emitting diodes of Examples 4 to 6 are also examples of the first embodiment, but represent examples in which the junction area between the active layer and each cladding layer was altered to 53,000 μm² (230 μm×230 μm).

### Example 4

With the exception of altering the junction area between the active layer and each cladding layer, the light-emitting diode of Example 6 was produced and evaluated under the same conditions as those described for Example 1.

The response time (tr), the emission output (P₀) and the forward voltage (V_{F}) were 15 nsec, 9.0 mW, and 2.0 V respectively.

### Example 5

With the exception of altering the number of pairs of the well layer and the barrier layer to three pairs, the light-emitting diode of Example 7 was produced and evaluated under the same conditions as those described for Example 6.

The response time (tr), the emission output (P₀) and the forward voltage (V_{F}) were 18 nsec, 9.3 mW, and 2.0 V respectively.

### Example 6

With the exception of altering the number of pairs of the well layer and the barrier layer to five pairs, the light-emitting diode of Example 8 was produced and evaluated under the same conditions as those described for Example 6.

The response time (tr), the emission output (P₀) and the forward voltage (V_{F}) were 22 nsec, 9.6 mW, and 2.0 V respectively.

### Example 7

The light-emitting diode of Example 7 is also an example of the first embodiment, but represents an example in which the junction area between the active layer and each cladding layer was altered to 20,000 μm² (200 μm×100 μm).

With the exception of altering the junction area between the active layer and each cladding layer, the light-emitting diode of Example 7 was produced and evaluated under the same conditions as those described for Example 1.

The response time (tr), the emission output (P₀) and the forward voltage (V_{F}) were 17 nsec, 9.6 mW, and 2.1 V respectively.

### Example 8

The light-emitting diode of Example 8 is also an example of the first embodiment, but represents an example in which the junction area between the active layer and each cladding layer was altered to 90,000 μm² (300 μm×300 μm).

With the exception of altering the junction area between the active layer and each cladding layer, the light-emitting diode of Example 8 was produced and evaluated under the same conditions as those described for Example 1.

The response time (tr), the emission output (P₀) and the forward voltage (V_{F}) were 23 nsec, 9.4 mW, and 2.0 V respectively.

Example 9 and Example 10 represent examples of the second embodiment.

### Example 9

The light-emitting diode of Example 9 represents an example in which the junction area between the active layer and each cladding layer was set to 123,000 μm² (350 μm×350 μm).

The layered structure of the light-emitting diode of Example 9 was as follows.

The GaAs substrate formed from monocrystalline Si-doped n-type GaAs had a growth plane inclined 15° from the (100) plane toward the (0-1-1) direction, and the carrier concentration was 2×10¹⁸ cm⁻³. The compound semiconductor layers included an n-type buffer layer formed from Si-doped GaAs, an n-type contact layer formed from Si-doped (Al_{0.7}Ga_{0.3})_{0.5}In_{0.5}P, an n-type upper cladding layer formed from Si-doped (Al_{0.7}Ga_{0.3})_{0.5}In_{0.5}P, an upper guide layer formed from (Al_{0.3}Ga_{0.7})_{0.5}In_{0.5}P, well layer/barrier layer pairs formed from Al_{0.17}Ga_{0.83}As/(Al_{0.1}Ga_{0.9})_{0.5}In_{0.5}P, a lower guide layer formed from (Al_{0.3}Ga_{0.7})_{0.5}In_{0.5}P, a p-type lower cladding layer formed from Mg-doped (Al_{0.7}Ga_{0.3})_{0.5}In_{0.5}P, a thin-film intermediate layer formed from (Al_{0.5}Ga_{0.5})_{0.5}In_{0.5}P, and a current diffusion layer formed from Mg-doped p-type GaP.

The buffer layer formed from GaAs had a carrier concentration of approximately 2×10¹⁸ cm⁻³ and a thickness of approximately 0.5 μm. The contact layer had a carrier concentration of approximately 2×10¹⁸ cm⁻³ and a thickness of approximately 3.5 μm. The upper cladding layer had a carrier concentration of approximately 1×10¹⁸ cm⁻³ and a thickness of approximately 0.5 μm. The upper guide layer was undoped and had a thickness of approximately 50 nm. The well layer was undoped and was formed from a layer of Al_{0.17}Ga_{0.83}As having a thickness of approximately 7 nm, whereas the barrier layer was undoped and was formed from a layer of (Al_{0.1}Ga_{0.9})_{0.5}In_{0.5}P having a thickness of approximately 19 nm. Further the number of pairs of the well layer and the barrier layer was specified as five pairs. The lower guide layer was undoped and had a thickness of approximately 50 nm. The lower cladding layer had a carrier concentration of approximately 8×10¹⁷ cm⁻³ and a thickness of approximately 0.5 μm. The intermediate layer had a carrier concentration of approximately 8×10¹⁷ cm⁻³ and a thickness of approximately 0.05 μm. The current diffusion layer formed from GaP had a carrier concentration of approximately 3×10¹⁸ cm⁻³ and a thickness of approximately 9 μm.

The response time (tr), the emission output (P₀) and the forward voltage (V_{F}) were 24 nsec, 9.0 mW, and 2.1 V respectively.

### Example 10

With the exceptions of altering the junction area between the active layer and each cladding layer to 53,000 μm² (230 μm×230 μm), and altering the number of pairs of the well layer and the barrier layer to three pairs, the light-emitting diode of Example 10 was produced and evaluated under the same conditions as those described for Example 9.

The response time (tr), the emission output (P₀) and the forward voltage (V_{F}) were 19 nsec, 9.0 mW, and 2.1 V respectively.

Examples 11 to 14 are examples in which the compound semiconductor layers were produced in the same manner as that described for examples 1 to 10, and a functional substrate containing a reflective layer was subsequently bonded to the current diffusion layer, with the functional substrate including a layer formed from Si. The light-emitting diodes of Examples 11 and 12 are examples of the third embodiment, and the light-emitting diodes of Examples 13 and 14 are examples of the fifth embodiment.

### Example 11

The light-emitting diode of Example 11 is an example in which the junction area between the active layer and each cladding layer was set to 123,000 μm² (350 μm×350 μm). The number of pairs of the well layer and the barrier layer was five pairs.

The method used for producing the light-emitting diode of Example 11 is described below with reference to FIG. 8B.

Eight electrodes 21, each composed of a dot of an AuBe/Au alloy having a thickness of 0.2 μm and a diameter of 20 μm, were formed on the surface of the current diffusion layer 8, with the electrodes 21 spaced at equal intervals at positions 50 μm from the edge of the light extraction surface.

Next, using a sputtering method, an ITO film 22 that functions as a transparent conductive film was formed with a thickness of 0.4 μm. A layer 23 composed of silver alloy/Ti/Au having a thickness of 0.2 μm/0.1 μm/1 μm was then formed as the reflective layer 23.

On the other hand, a layer 32 composed of Ti/Au/In having a thickness of 0.1 μm/0.5 μm/0.3 μm was formed on the surface of a silicon substrate (a layer formed from silicon) 30. A layer 33 composed of Ti/Au having a thickness of 0.1 μm/0.5 μm was formed on the back surface of the silicon substrate 30. The Au surface of the light-emitting diode wafer and the In surface of the silicon substrate were then brought together, and heated under pressure at 320° C. and 500 g/cm², thus bonding the functional substrate to the light-emitting diode wafer.

The GaAs substrate was removed, an ohmic electrode 25 composed of AuGe/Au having a diameter of 100 μm and a thickness of 3 μm was formed on the surface of the contact layer 16, and the p- and n-ohmic electrodes were then subjected to an alloying treatment by heating at 420° C. for 5 minutes.

Next, the surface of the contact layer 16 was subjected to a surface roughening treatment.

The semiconductor layer, the reflective layer and the eutectic metal were removed from those sections to be cut as part of the chip separation process, and the silicon substrate was then cut into squares with a dicing saw at a pitch of 350 μm.

As shown in Table 6, the results of evaluating the properties of this light-emitting diode (light-emitting diode lamp) revealed that the response time (tr), the emission output (P₀) and the forward voltage (V_{F}) were 25 nsec, 8.6 mW, and 2.0 V respectively.

### Example 12

With the exceptions of altering the junction area between the active layer and each cladding layer to 53,000 μm² (230 μm×230 μm), and altering the number of pairs of the well layer and the barrier layer to three pairs, the light-emitting diode of Example 12 was produced and evaluated under the same conditions as those described for Example 11.

As shown in Table 6, the results of evaluating the properties of this light-emitting diode (light-emitting diode lamp) revealed that the response time (tr), the emission output (P₀) and the forward voltage (V_{F}) were 18 nsec, 8.5 mW, and 2.0 V respectively.

### Example 13

In the light-emitting diode of Example 13, the junction area between the active layer and each cladding layer was set to 123,000 μm² (350 μm×350 μm), and the number of pairs of the well layer and the barrier layer was five pairs. Following production of the compound semiconductor layers using the same procedure as Example 9, the same procedure as that described for Example 11 was used to bond a functional substrate having a reflective layer to the current diffusion layer.

As shown in Table 6, the results of evaluating the properties of this light-emitting diode (light-emitting diode lamp) revealed that the response time (tr), the emission output (P₀) and the forward voltage (V_{F}) were 25 nsec, 8.0 mW, and 2.1 V respectively.

### Example 14

With the exceptions of altering the junction area between the active layer and each cladding layer to 53,000 μm² (230 μm×230 μm), and altering the number of pairs of the well layer and the barrier layer to three pairs, the light-emitting diode of Example 14 was produced and evaluated under the same conditions as those described for Example 13.

The response time (tr), the emission output (P₀) and the forward voltage (V_{F}) were 19 nsec, 8.0 mW, and 2.1 V respectively.

Examples 15 and 16 represent an example of the fourth embodiment and an example of the sixth embodiment respectively, and are structures in which the compound semiconductor layers were produced in the same manner as that described for examples 1 to 10, and a functional substrate containing a reflective layer and a metal substrate was subsequently bonded to the current diffusion layer.

### Example 15

In the light-emitting diode of Example 15, the junction area between the active layer and each cladding layer was set to 123,000 μm² (350 μm×350 μm), and the number of pairs of the well layer and the barrier layer was five pairs.

The method used for producing the light-emitting diode of Example 15 is described below with reference to FIG. 11. The contact layer and the ohmic electrode (first electrode) had the same structures as those illustrated in FIG. 8B, and therefore the reference symbols for the contact layer 16 and the ohmic electrode 25 correspond with the symbols shown in FIG. 8B.

Eight electrodes 57, each composed of a dot of an AuBe/Au alloy having a thickness of 0.2 μm and a diameter of 20 μm, were formed on the surface of the current diffusion layer 8, with the electrodes 57 spaced at equal intervals at positions 50 μm from the edge of the light extraction surface.

Next, using a sputtering method, an ITO film 52 that functions as a transparent conductive film was formed with a thickness of 0.4 μm. A layer 53 composed of silver alloy/Ti/Au having a thickness of 0.2 μm/0.1 μm/1 μm was then formed as the reflective layer 53.

Subsequently, using a first metal sheet having a coefficient of thermal expansion greater than that of the material of the compound semiconductor layer 2, and a second metal sheet having a coefficient of thermal expansion smaller than that of the material of the compound semiconductor layer 2, a metal substrate 50 was formed by hot pressing.

For example, using a Cu sheet having a thickness of 10 μm as the first metal sheet 50A and a Mo sheet having a thickness of 75 μm as the second metal sheet 50B, the second metal sheet 50B was inserted between two sheets of the first metal sheet 50A, as illustrated in FIG. 11, and a prescribed pressure apparatus was then used to apply a load under high temperature conditions, thereby forming a metal substrate 50 having a three-layer structure composed of Cu (10 μm)/Mo (75 μm)/Cu (10 μm).

Next, the surface of the reflective layer 53 of the light-emitting diode and the surface of the metal substrate 50 were brought together, and heated under pressure at 400° C. and 500 g/cm², thus bonding the functional substrate to the light-emitting diode wafer.

The GaAs substrate was removed, an ohmic electrode 25 (see FIG. 8B) composed of AuGe/Au having a diameter of 100 μm and a thickness of 3 μm was formed on the surface of the contact layer 16 (see FIG. 8B), and the p- and n-ohmic electrodes were then subjected to an alloying treatment by heating at 420° C. for 5 minutes.

Next, the surface of the contact layer 16 (see FIG. 8B) was subjected to a surface roughening treatment.

The semiconductor layer, the reflective layer and the eutectic metal were removed from those sections to be cut as part of the chip separation process, and the silicon substrate was then cut into squares with a dicing saw at a pitch of 350 μm.

As shown in Table 6, the results of evaluating the properties of this light-emitting diode (light-emitting diode lamp) revealed that the response time (tr), the emission output (P₀) and the forward voltage (V_{F}) were 25 nsec, 8.6 mW, and 2.0 V respectively.

### Example 16

The light-emitting diode of Example 16 differs from the light-emitting diode of Example 15 in that the AlGaAs barrier layer from Example 15 has been replaced with a barrier layer formed from a compound semiconductor having a composition formula of (Al_{X3}Ga_{1-X3})_{Y2}In_{1-Y2}P (wherein 0≦X3≦1 and 0≦Y2≦1).

As shown in Table 6, the results of evaluating the properties of this light-emitting diode (light-emitting diode lamp) revealed that the response time (tr), the emission output (P₀) and the forward voltage (V_{F}) were 25 nsec, 8.0 mW, and 2.1 V respectively.

Reference Examples 1 to 4 are examples in which the number of pairs of the well layer and the barrier layer was increased to either 10 pairs or 20 pairs, and describe structures suited to high emission output in which a ternary mixed crystal quantum well structure, or a quantum well structure composed of a ternary mixed crystal well layer and a quaternary mixed crystal barrier layer, was sandwiched between quaternary cladding layers in the manner described in the present invention.

### Reference Example 1

With the exception of increasing the number of pairs of the well layer and the barrier layer to 10 pairs, the light-emitting diode of Reference Example 1 was produced and evaluated under the same conditions as those described for the light-emitting diode of Example 1.

As shown in Table 6, the results of evaluating the properties of this light-emitting diode (light-emitting diode lamp) revealed that the response time (tr), the emission output (P₀) and the forward voltage (V_{F}) were 30 nsec, 9.8 mW, and 2.0 V respectively.

### Reference Example 2

With the exception of increasing the number of pairs of the well layer and the barrier layer to 20 pairs, the light-emitting diode of Reference Example 2 was produced and evaluated under the same conditions as those described for the light-emitting diode of Example 1.

As shown in Table 6, the results of evaluating the properties of this light-emitting diode (light-emitting diode lamp) revealed that the response time (tr), the emission output (P₀) and the forward voltage (V_{F}) were 42 nsec, 10 mW, and 2.0 V respectively.

### Reference Example 3

With the exception of increasing the number of pairs of the well layer and the barrier layer to 10 pairs, the light-emitting diode of Reference Example 3 was produced and evaluated under the same conditions as those described for the light-emitting diode of Example 4.

As shown in Table 6, the results of evaluating the properties of this light-emitting diode (light-emitting diode lamp) revealed that the response time (tr), the emission output (P₀) and the forward voltage (V_{F}) were 28 nsec, 10 mW, and 2.0 V respectively.

### Reference Example 4

With the exception of increasing the number of pairs of the well layer and the barrier layer to 20 pairs, the light-emitting diode of Reference Example 4 was produced and evaluated under the same conditions as those described for the light-emitting diode of Example 1.

As shown in Table 6, the results of evaluating the properties of this light-emitting diode (light-emitting diode lamp) revealed that the response time (tr), the emission output (P₀) and the forward voltage (V_{F}) were 38 nsec, 10.5 mW, and 2.0 V respectively.

### Comparative Example 1

Comparative Example 1 illustrates an example of a light-emitting diode having an emission wavelength of 730 nm produced by growing thick layers using a liquid phase epitaxial method and then removing the substrate.

Using a sliding boat growth apparatus, AlGaAs layers were grown on a GaAs substrate.

A p-type GaAs substrate was set in the substrate-holding slot in the sliding boat growth apparatus, and Ga metal, polycrystalline GaAs, metallic Al, and a dopant were placed in the crucibles prepared for growing each layer.

The layers grown constituted a four-layer structure composed of a transparent thick film layer (first p-type layer), a lower cladding layer (p-type cladding layer), an active layer, and an upper cladding layer (n-type cladding layer), and the layers were stacked in this order.

The sliding boat growth apparatus in which the aforementioned raw materials had been set was placed in a quartz reaction tube, and heated to 950° C. under a stream of hydrogen to melt the raw materials. Subsequently, the atmospheric temperature was reduced to 910° C., the slider was pushed toward the right so as to make contact with the raw material solution (melt), and the temperature was reduced at a rate of 0.5° C./minute until a predetermined temperature was reached. The slider was then pushed again so as to sequentially make contact with each of the raw material solutions, and the aforementioned high-temperature operation was repeated, until the slider was brought into contact with the final melt. The atmospheric temperature was then reduced to 703° C. to grow the n-type cladding layer. Subsequently, the slider was pushed so as to separate the raw material solutions and the wafer, thereby completing the epitaxial growth.

The structure of the thus obtained epitaxial layers included the first p-type layer having an Al composition X1=0.3 to 0.4, a thickness of 64 μm and a carrier concentration of 3×10¹⁷ cm⁻³, the p-type cladding layer having an Al composition X2=0.4 to 0.5, a thickness of 79 μm and a carrier concentration of 5×10¹⁷ m⁻³, the p-type active layer that exhibited an emission wavelength of 760 nm and had a thickness of 1 μm and a carrier concentration of 1×10¹⁸ cm⁻³, and the n-type cladding layer having an Al composition X4=0.4 to 0.5, a thickness of 25 μm and a carrier concentration of 5×10¹⁷ cm⁻³.

Following completion of the epitaxial growth, the epitaxial substrate was removed from the apparatus, the surface of the n-type GaAlAs cladding layer was protected, and the p-type GaAs substrate was selectively removed using an ammonia-hydrogen peroxide-based etchant. Subsequently, gold electrodes were formed on both surfaces of the epitaxial wafer, and using an electrode mask having a length along one long side of 350 μm, a surface electrode having a centrally positioned wire bonding pad with a diameter of 100 μm was formed. Ohmic electrodes having a diameter of 20 μm were formed at intervals of 80 μm as the back electrode. By performing subsequent dicing, separation and etching, 350 μM square light-emitting diodes having an n-type GaAlAs layer as the surface layer were produced.

The results of evaluating a light-emitting diode lamp prepared by mounting the light-emitting diode of Comparative Example 1 are shown in Table 6.

As shown in Table 6, when a current was passed between the n-type and p-type ohmic electrodes, red light having a peak wavelength of 760 nm was emitted. Further, the forward voltage (V_{F}) observed when an electric current of 20 milliamperes (mA) flowed though the device in the forward direction was 1.9 volts (V).

The response time (tr) and the emission output (P₀) when the forward current was 20 mA were 25 nsec and 3.0 mW respectively.

In each of the samples of Comparative Example 1, the response time was either equal to, or slower than, that observed in Examples 1 to 16 of the present invention, and the emission output was lower.

### INDUSTRIAL APPLICABILITY

The light-emitting diode, the light-emitting diode lamp and the illumination device of the present invention can be used as a light-emitting diode, a light-emitting diode lamp, and an illumination device that emit red light and/or infrared light, and combine rapid response characteristics with high output characteristics.

### DESCRIPTION OF THE REFERENCE SYMBOLS

1: Light-emitting diode
2: Compound semiconductor layer
3: Functional substrate
3a: Vertical surface
3b: Inclined surface
4: n-type ohmic electrode (first electrode)
5: p-type ohmic electrode (second electrode)
6: Third electrode
7: Light-emitting unit
8: Current diffusion layer
9: Lower cladding layer
10: Lower guide layer
11: Light-emitting (active) layer
12: Upper guide layer
13: Upper cladding layer
14: GaAs substrate
15: Buffer layer
16: Contact layer
17: Well layer
18: Barrier layer
20: Light-emitting diode
21: Electrode
22: Transparent conductive film
23: Reflective layer
25: Bonding electrode
30: Silicon substrate
31: Functional substrate
41: Light-emitting diode lamp
42: Mounting substrate
43: n-electrode terminal
44: p-electrode terminal
45, 46: Gold wire
47: Epoxy resin
α: Angle between inclined surface and surface parallel to light emission surface
50: Metal substrate
51: Functional substrate
52: Transparent conductive film
53: Reflective layer
55: First electrode
56: Contact layer
57: Second electrode

1. A light-emitting diode comprising:
a light-emitting unit, containing an active layer having a quantum well structure prepared by alternately stacking a well layer and a barrier layer each formed from a compound semiconductor having a composition formula of (Al_{X1}Ga_{1-X1})As (wherein 0≦X1≦1), and a first cladding layer and a second cladding layer that sandwich the active layer,
a current diffusion layer formed on the light-emitting unit, and
a functional substrate bonded to the current diffusion layer, wherein
the first cladding layer and the second cladding layer are formed from a compound semiconductor having a composition formula of (Al_{X2}Ga_{1-X2})_{Y1}In_{1-Y1}P (wherein 0≦X2≦1 and 0≦Y1≦1), and
the number of pairs of the well layer and the barrier layer is not more than five.

2. A light-emitting diode comprising:
a light-emitting unit, containing an active layer having a quantum well structure prepared by alternately stacking a well layer formed from a compound semiconductor having a composition formula of (Al_{X1}Ga_{1-X1})As (wherein 0≦X1≦1) and a barrier layer formed from a compound semiconductor having a composition formula of (Al_{X3}Ga_{1-X3})_{Y2}In_{1-Y2}P (wherein 0≦X3≦1 and 0≦Y2≦1), and a first cladding layer and a second cladding layer that sandwich the active layer,
a current diffusion layer formed on the light-emitting unit, and
a functional substrate bonded to the current diffusion layer, wherein
the first cladding layer and the second cladding layer are formed from a compound semiconductor having a composition formula of (Al_{X2}Ga_{1-X2})_{Y1}In_{1-Y1}P (wherein 0≦X2≦1 and 0≦Y1≦1), and
the number of pairs of the well layer and the barrier layer is not more than five.

3. The light-emitting diode according to claim 1, wherein a junction area between the active layer and each cladding layer is within a range from 20,000 to 90,000 μm².

4. The light-emitting diode according to claim 1, wherein an Al composition X1 of the well layer satisfies 0.20≦X1≦0.36, a thickness of the well layer is within a range from 3 to 30 nm, and an emission wavelength is set to 660 to 720 nm.

5. The light-emitting diode according to claim 1, wherein an Al composition X1 of the well layer satisfies 0≦X1≦0.2, a thickness of the well layer is within a range from 3 to 30 nm, and an emission wavelength is set to 720 to 850 nm.

6. The light-emitting diode according to claim 1, wherein the functional substrate is transparent to an emission wavelength.

7. The light-emitting diode according to claim 1, wherein the functional substrate is formed from GaP, sapphire or SiC.

8. A light-emitting diode comprising:
a light-emitting unit, containing an active layer having a quantum well structure prepared by alternately stacking a well layer and a barrier layer each formed from a compound semiconductor having a composition formula of (Al_{X1}Ga_{1-X1})As (wherein 0≦X1≦1), and a first cladding layer and a second cladding layer that sandwich the active layer,
a current diffusion layer formed on the light-emitting unit, and
a functional substrate, which comprises a reflective layer that is disposed facing the light-emitting unit and has a reflectance of at least 90% relative to an emission wavelength, and which is bonded to the current diffusion layer, wherein
the first cladding layer and the second cladding layer are formed from a compound semiconductor having a composition formula of (Al_{X2}Ga_{1-X2})_{Y1}In_{1-Y1}P (wherein 0≦X2≦1 and 0≦Y1≦1), and
the number of pairs of the well layer and the barrier layer is not more than five.

9. A light-emitting diode comprising:
a light-emitting unit, containing an active layer having a quantum well structure prepared by alternately stacking a well layer formed from a compound semiconductor having a composition formula of (Al_{X1}Ga_{1-X1})As (wherein 0≦X1≦1) and a barrier layer formed from a compound semiconductor having a composition formula of (Al_{X3}Ga_{1-X3})₂In_{1-Y2}P (wherein 0≦X3≦1 and 0≦Y2≦1), and a first cladding layer and a second cladding layer that sandwich the active layer,
a current diffusion layer formed on the light-emitting unit, and
a functional substrate, which comprises a reflective layer that is disposed facing the light-emitting unit and has a reflectance of at least 90% relative to the emission wavelength, and which is bonded to the current diffusion layer, wherein
the first cladding layer and the second cladding layer are formed from a compound semiconductor having a composition formula of (Al_{X2}Ga_{1-X2})_{Y1}In_{1-Y1}P (wherein 0≦X2≦1 and 0≦Y1≦1), and
the number of pairs of the well layer and the barrier layer is not more than five.

10. The light-emitting diode according to claim 8, wherein a junction area between the active layer and each cladding layer is within a range from 20,000 to 90,000 μm².

11. The light-emitting diode according to claim 8, wherein an Al composition X1 of the well layer satisfies 0.20≦X1≦0.36, a thickness of the well layer is within a range from 3 to 30 nm, and an emission wavelength is set to 660 to 720 nm.

12. The light-emitting diode according to claim 8, wherein an Al composition X1 of the well layer satisfies 0≦X1≦0.2, a thickness of the well layer is within a range from 3 to 30 nm, and an emission wavelength is set to 720 to 850 nm.

13. The light-emitting diode according to claim 8, wherein the functional substrate comprises a layer formed from silicon or germanium.

14. The light-emitting diode according to claim 8, wherein the functional substrate comprises a metal substrate.

15. The light-emitting diode according to claim 14, wherein the metal substrate is formed from two or more metal layers.

16. The light-emitting diode according to claim 1, wherein the current diffusion layer is formed from GaP.

17. The light-emitting diode according to claim 1, wherein a thickness of the current diffusion layer is within a range from 0.5 to 20 μm.

18. The light-emitting diode according to claim 1, wherein the side surface of the functional substrate has a vertical surface, which is positioned relatively closer to the light-emitting unit and is substantially perpendicular to a main light extraction surface, and an inclined surface, which is positioned relatively distant from the light-emitting unit and is inclined inward relative to the main light extraction surface.

19. The light-emitting diode according to claim 18, wherein the light extraction surface comprises a rough surface.

20. The light-emitting diode according to claim 18, wherein a first electrode and a second electrode are provided on the light-emitting diode on the side of the main light extraction surface.

21. The light-emitting diode according to claim 20, wherein the first electrode and the second electrode are ohmic electrodes.

22. The light-emitting diode according to claim 20, further comprising a third electrode, which is provided on a surface of the functional substrate on an opposite side to a surface facing the main light extraction surface.

23. A light-emitting diode lamp, comprising the light-emitting diode according to claim 1.

24. A light-emitting diode lamp, comprising the light-emitting diode according to claim 22, wherein the first electrode or the second electrode, and the third electrode are connected substantially equipotentially.

25. An illumination device, equipped with two or more of the light-emitting diode according to claim 1.
